(19) United States
(12) Patent Application Publication
(10) Pub. No.: US 2025/0338771 A1
(43) Pub. Date: Oct. 30, 2025

(54) LIGHT-EMITTING ELEMENT AND ELECTRONIC APPARATUS

(71) Applicant: SONY GROUP CORPORATION, TOKYO (JP)

(72) Inventors: YASUHARU UJIIE, TOKYO (JP); MARI ICHIMURA, TOKYO (JP); CHIAKI TAKAHASHI, TOKYO (JP)

(21) Appl. No.: 18/849,486

(22) PCT Filed: Mar. 9, 2023
(86) PCT No.: PCT/JP2023/009141

§ 371 Date: Sep. 21, 2024

(30) Foreign Application Priority Data
Mar. 30, 2022 (JP) 2022-056823

(51) Int. Cl. H10K 85/60; C09K 11/02; H10K 50/12; H10K 102/00

(52) U.S. Cl. CPC H10K 85/6576; C09K 11/02; H10K 50/12; H10K 2102/331

(57) ABSTRACT

A first semiconductor element according to an embodiment of the present disclosure includes: a first electrode; a second electrode disposed to be opposed to the first electrode; and an organic layer provided between the first electrode and the second electrode, and including a light-emitting layer, the light-emitting layer including at least one kind of a heteroacene derivative having, in a molecule, one skeleton represented by a general formula (1) or a general formula (2).

### TECHNICAL FIELD

The present disclosure relates to a light-emitting element and an electronic apparatus that use an organic semiconductor.

### BACKGROUND ART

In recent years, development has been progressing of electronic apparatuses using organic semiconductors in place of inorganic semiconductors. For example, PTL 1 describes organic semiconductors each including a combination of fluorene and carbazole. These organic semiconductors are used for a hole injection layer or a hole transport layer of an organic electroluminescent element, and are known as materials having excellent hole transportability.

### CITATION LIST

### Patent Literature

PTL 1: European Patent Application Publication No. 2881446

### SUMMARY OF THE INVENTION

Incidentally, a light-emitting element using an organic semiconductor is desired to have improved electrical properties typified by a drive voltage, a light emission external quantum yield, and light emission electric power efficiency.

It is desirable to provide a light-emitting element and an electronic apparatus having an excellent electrical property.

A light-emitting element according to an embodiment of the present disclosure includes: a first electrode; a second electrode disposed to be opposed to the first electrode; and an organic layer provided between the first electrode and the second electrode, and including a light-emitting layer, the light-emitting layer including at least one kind of a heteroacene derivative having, in a molecule, one skeleton represented by a general formula (1) or a general formula (2) below.

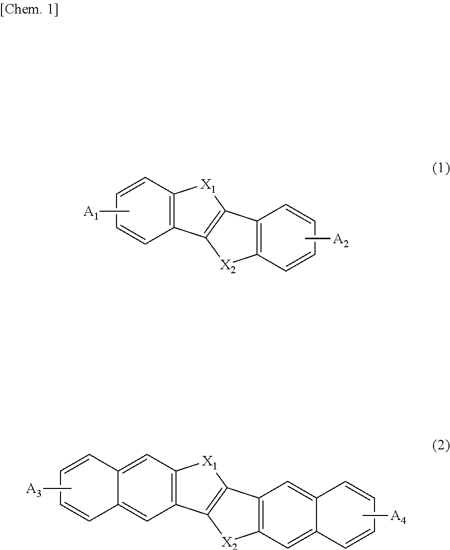

(X1 to X4 are each one of sulfur, oxygen, selenium, or tellurium; and A1 to A4 are each independently a hydrogen atom, an aryl group, a heteroaryl group, an alkyl group, an aryloxy group, a heteroaryloxy group, or an alkoxy group, or a derivative thereof.)

An electronic apparatus according to an embodiment of the present disclosure includes the light-emitting element according to the above-described embodiment of the present disclosure.

In the light-emitting element according to the embodiment of the present disclosure and the electronic apparatus according to the embodiment of the present disclosure, the light-emitting layer between the first electrode and the second electrode includes at least one kind of the heteroacene derivative having, in a molecule, one skeleton represented by the general formula (1) or the general formula (2) described above. This improves carrier transportability and improves efficiency of transfer of energy to a dopant material in the light-emitting layer.

### BRIEF DESCRIPTION OF THE DRAWINGS

FIG. 1 is a schematic cross-sectional view of an example of a light-emitting element according to an embodiment of the present disclosure.

FIG. 2 is a diagram illustrating an example of energy levels of materials included in respective layers of the light-emitting element illustrated in FIG. 1.

FIG. 3 is a diagram illustrating another example of the energy levels of the materials included in the respective layers of the light-emitting element illustrated in FIG. 1.

FIG. 4 is an explanatory diagram of transfer of carriers generated in the light-emitting element illustrated in FIG. 1.

FIG. 5 is a plan view of a configuration of a display device including the light-emitting elements illustrated in FIG. 1.

FIG. 6 is a diagram illustrating an example of a pixel drive circuit illustrated in FIG. 5.

FIG. 7A is a schematic cross-sectional view of an example of a light-emitting element according to a modification example of the present disclosure.

FIG. 7B is a schematic cross-sectional view of another example of the light-emitting element according to the modification example of the present disclosure.

FIG. 8 is a plan view of a schematic configuration of a module including the above-described display device.

FIG. 9 is a perspective view of an appearance of a display device according to Application Example 1 of the present disclosure.

FIG. 10A is a perspective view of an appearance of a smartphone according to Application Example 2 of the present disclosure, as viewed from a front side.

FIG. 10B is a perspective view of an appearance of the smartphone illustrated in FIG. 10A, as viewed from a back side.

FIG. 11A is a perspective view of an example of an appearance of a tablet according to Application Example 3 of the present disclosure.

FIG. 11B is a perspective view of another example of the appearance of the tablet according to Application Example 3 of the present disclosure.

FIG. 12 is a perspective view of an appearance of Application Example 4 of the present disclosure.

FIG. 13A is a view of an appearance of a digital camera according to Application Example 5 of the present disclosure, as viewed from a front side.

FIG. 13B is a view of the appearance of the digital camera according to Application Example 5 of the present disclosure, as viewed from a back side.

FIG. 14 is a perspective view of an appearance of a head-mounted display according to Application Example 6 of the present disclosure.

FIG. 15 is a schematic cross-sectional view of a portion of a configuration of a laser Doppler blood flowmeter according to Application Example 7 of the present disclosure.

FIG. 16 is a perspective view of an appearance of a wristband electronic apparatus according to Application Example 8 of the present disclosure.

FIG. 17 is an explanatory schematic cross-sectional view of an internal structure of a body unit of the wristband electronic apparatus according to Application Example 8 of the present disclosure.

FIG. 18 is an explanatory view of a module including the light-emitting elements and a photoelectric conversion element.

FIG. 19 is a diagram illustrating energy levels of host materials and a dopant material used in Experimental Examples 1 to 3.

FIG. 20 is a graph illustrating absorption of the host material and the dopant material used in Experimental Example 1.

FIG. 21 is a graph illustrating absorption of the host material and the dopant material used in Experimental Example 2.

FIG. 22 is a graph illustrating absorption of the host material and the dopant material used in Experimental Example 3.

FIG. 23 is a graph illustrating a relationship between light emission electric power efficiency and current density in Experimental Examples 1 to 3.

### MODES FOR CARRYING OUT THE INVENTION

Hereinafter, detailed description is given of an embodiment of the present disclosure with reference to the drawings. The following description is a specific example of the present disclosure, and the present disclosure is not limited to the following embodiment. Further, the present disclosure is also not limited to arrangements, dimensions, dimensional ratios, and the like of respective components illustrated in each drawing. It is to be noted that the description is given in the following order.
1. Embodiment (an Example of a Light-Emitting Element Including a Light-Emitting Layer Using a Heteroacene Derivative as a Host Material)
   1-1. Configuration of Light-Emitting Element
   1-2. Configuration of Display Device
   1-3. Workings and Effects
2. Modification Example (An example of a stacked light-emitting element)
3. Application Examples
4. Examples

### 1. EMBODIMENT

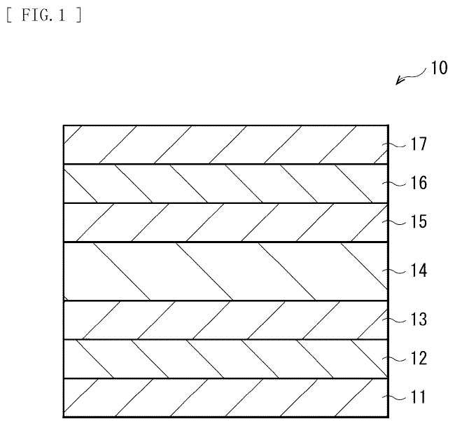

FIG. 1 schematically illustrates an example of a cross-sectional configuration of a light-emitting element (a light-emitting element 10) according to an embodiment of the present disclosure. The light-emitting element 10 is, for example, a so-called organic electroluminescent element (an organic EL element) usable as a light source in an organic EL television and the like. The light-emitting element 10 according to the present embodiment corresponds to a specific example of a “light-emitting element” of the present disclosure, and includes an organic layer (a light-emitting layer 14) including at least one kind of a heteroacene derivative having, in a molecule, one skeleton represented by a general formula (1) or a general formula (2) described later.

### (1-1. Configuration of Light-Emitting Element)

In the light-emitting element 10, an organic stacked film including the light-emitting layer 14 is sandwiched between a pair of electrodes opposed to each other. Applying a voltage thereto causes holes and electrons to be recombined in the light-emitting layer 14, thereby emitting light. The light-emitting element 10 has, for example, a configuration in which an anode 11, a hole injection layer 12, a hole transport layer 13, the light-emitting layer 14, an electron transport layer 15, an electron injection layer 16, and a cathode 17 are stacked in this order.

The anode 11 injects holes into the light-emitting layer 14. For example, in a case where light emission in the light-emitting layer 14 is extracted from a side of the anode 11, the anode 11 is configured by an electrically conductive film having light transmissivity. Examples of a constituent material of the anode 11 include an electrically conductive metal oxide. Specific examples thereof include indium oxide (In₂O₃), and indium tin oxide (ITO) that is In₂O₃ doped with tin (Sn) as a dopant. As for crystallinity, the ITO thin film may have high crystallinity or low crystallinity (close to amorphous). Examples of the constituent material of the anode 11 include, in addition to the above, IFO that is In₂O₃ doped with fluorine (F) as a dopant. In addition, examples thereof include a tin oxide (SnO₂)-based material doped with a dopant, such as ATO doped with Sb as a dopant or FTO doped with F as a dopant. Further, zinc oxide (ZnO) or a zinc oxide-based material doped with a dopant may be used. Examples of the ZnO-based material include aluminum zinc oxide (AZO) aluminum (Al) as a dopant, gallium-zinc oxide (GZO) doped with gallium (Ga), boron zinc oxide doped with boron (B), and indium-zinc oxide (IZO) doped with indium (In). Furthermore, indium-gallium oxide (IGO) doped with indium as a dopant or indium-gallium-zinc oxide (IGZO, In—GaZnO₄) doped with indium and gallium as dopants may be used. In addition, tin oxide (SnOₓ), titanium oxide (TiOx), antimony oxide (SbOₓ), tungsten oxide (WOₓ), molybdenum oxide (MoOₓ), a spinel oxide, or an oxide having a YbFe2O4 structure may be used as the constituent material of the anode 11. In addition, examples of the constituent material of the anode 11 may include an electrically conductive material including, as a main component, gallium oxide, titanium oxide, niobium oxide, nickel oxide, or the like.

The anode 11 has, for example, a thickness of 2×10⁻⁸ m or more and 2×10⁻⁷ m or less, preferably 3×10⁻⁸ m or more and 1.5×10⁻⁷ m or less.

In a case where there is no necessity that the anode 11 has light transmissivity (e.g., in a case where light emission in the light-emitting layer 14 is extracted from a side of the cathode 17), it is possible to use a single metal or an alloy having a high work function (e.g., φ=4.5 eV to 5.5 eV). Specific examples thereof include Al—Nd (an alloy of aluminum and neodymium), Al—Cu (an alloy of aluminum and copper), Al—Sm—Cu (an alloy of aluminum, samarium, and copper), and Ag—Pd—Cu (an alloy of silver, palladium, and copper). In addition, examples of the material included in the anode 11 include gold (Au), silver (Ag), chromium (Cr), nickel (Ni), palladium (Pd), platinum (Pt), iron (Fe), iridium (Ir), germanium (Ge), osmium (Os), rhenium (Re), and tellurium (Te), and alloys thereof. Further, the anode 11 may include a stacked film in which the above-described metal oxide such as ITO is stacked on the above-described metal thin film.

Further, examples of the material included in the anode 11 include electrically conductive substances, including a metal such as Pt, Au, Pd, Cr, Ni, Al, Ag, Ta, W, Cu, Ti, In, Sn, Fe, Co, or Mo, alloys including these metal elements, electrically conductive particles including these metals, electrically conductive particles of alloys including these metals, polysilicon containing an impurity, a carbon-based material, an oxide semiconductor, a carbon nanotube, and graphene. In addition, the anode 11 may include a stacked film of layers including the above-described metal elements.

Furthermore, examples of the material included in the anode 11 include an organic material (an electrically conductive macromolecule) such as poly(3,4-ethylenedioxythiophene)/polystyrene sulfonate [PEDOT/PSS]. The above-described electrically conductive materials may be mixed with a binder (a macromolecule) into a paste or an ink, and the paste or the ink may be cured and used as the anode 11.

Moreover, metal nanoparticles may be caused to adhere onto the anode 11. Preferably, gold (Au), silver (Ag), or copper (Cu) is selected as the metal nanoparticles. Causing such metal nanoparticles to adhere onto the anode 11 makes it possible to achieve a plasmon resonance effect to improve light emission efficiency of the light-emitting element 10.

The hole injection layer 12 may be provided between the anode 11 and the light-emitting layer 14. The hole injection layer 12 is adapted to improve electrical coupling between the anode 11 and the hole transport layer 13. Examples of a material included in the hole injection layer 12 include a hexaazatriphenylene derivative, a hexaazatrinaphthylene derivative, a metal complex including a heterocyclic compound as a ligand, a thiophene derivative, a thienoacene-based material, a heteroacene-based material, poly(3,4-ethylenedioxythiophene)/polystyrene sulfonate [PEDOT/PSS], polyaniline, molybdenum oxide (MoOₓ), ruthenium oxide (RuOₓ), vanadium oxide (VOₓ), WOₓ, naphthalenetetracarboxylic acid diimide, and naphthalenedicarboxylic acid monoimide.

The hole transport layer 13 is adapted to improve electrical coupling between the anode 11 and the light-emitting layer 14. In addition, the hole transport layer 13 is adapted to adjust light interference of the light-emitting element 10. The hole transport layer 13 corresponds to a specific example of a “first buffer layer” of the present disclosure. Examples of a material included in the hole transport layer 13 include an aromatic amine-based material, a carbazole derivative, an indolocarbazole derivative, a naphthalene derivative, an anthracene derivative, a phenanthrene derivative, a pyrene derivative, a perylene derivative, a tetracene derivative, a pentacene derivative, a perylene derivative, a picene derivative, a chrysene derivative, a fluoranthene derivative, a phthalocyanine derivative, a subphthalocyanine derivative, a hexaazatriphenylene derivative, a metal complex including a heterocyclic compound as a ligand, a thiophene derivative, a thienoacene-based material, a heteroacene-based material, poly(3,4-ethylenedioxythiophene)/polystyrene sulfonate [PEDOT/PSS], and polyaniline. Examples of the aromatic amine-based material include a triarylamine compound, a benzidine compound, and a styrylamine compound. Examples of the thienoacene-based material include a thienothiophene (TT) derivative, a benzothiophene (BT) derivative, a benzothienobenzothiophene (BTBT) derivative, a dinaphthothienothiophene (DNTT) derivative, a dianthracenothienothiophene (DATT) derivative, a benzobisbenzothiophene (BBBT) derivative, a thienobisbenzothiophene (TBBT) derivative, a dibenzothienobisbenzothiophene (DBTBT) derivative, a dithienobenzodithiophene (DTBDT) derivative, a dibenzothienodithiophene (DBTDT) derivative, a benzodithiophene (BDT) derivative, a naphthodithiophene (NDT) derivative, an anthracenodithiophene (ADT) derivative, a tetracenodithiophene (TDT) derivative, and a pentacenodithiophene (PDT) derivative. Among the above-described materials, it is preferable to use the thienoacene-based material as another material included in the hole transport layer 13. This makes it possible to suppress an increase in a drive voltage of the light-emitting element 10 even in a case where the hole transport layer 13 is thickened to impart a function of adjusting the light interference. Further, among the thienoacene-based materials, it is preferable to use a material having small absorption in a visible light region and a near-infrared region.

In addition, the hole transport layer 13 may include a metal oxide such as MoOₓ, RuOₓ, VOₓ, or WOₓ.

The hole transport layer 13 may be a single layer film using one kind or two or more kinds of the above-described materials, or may be a stacked film using one kind or two or more kinds of the above-described materials.

The hole transport layer 13 has, for example, a thickness of 5×10⁻⁹ m or more and 5×10⁻⁷ m or less, preferably 5×10⁻⁹ m or more and 2×10⁻⁷ m or less, and more preferably 5×10⁻⁹ m or more and 1×10⁻⁷ m or less.

The light-emitting layer 14 is a region in which holes injected from the anode 11 and electrons injected from the cathode 17 are recombined upon application of an electric field to the anode 11 and the cathode 17. The light-emitting layer 14 includes, for example, two or more kinds of materials. Two kinds of the materials included in the light-emitting layer 14 are referred to as a host material and a dopant material. In the typical light-emitting layer 14, it is possible to obtain desired light emission by recombining holes and electrons in the host material and transferring resulting energy to the dopant material.

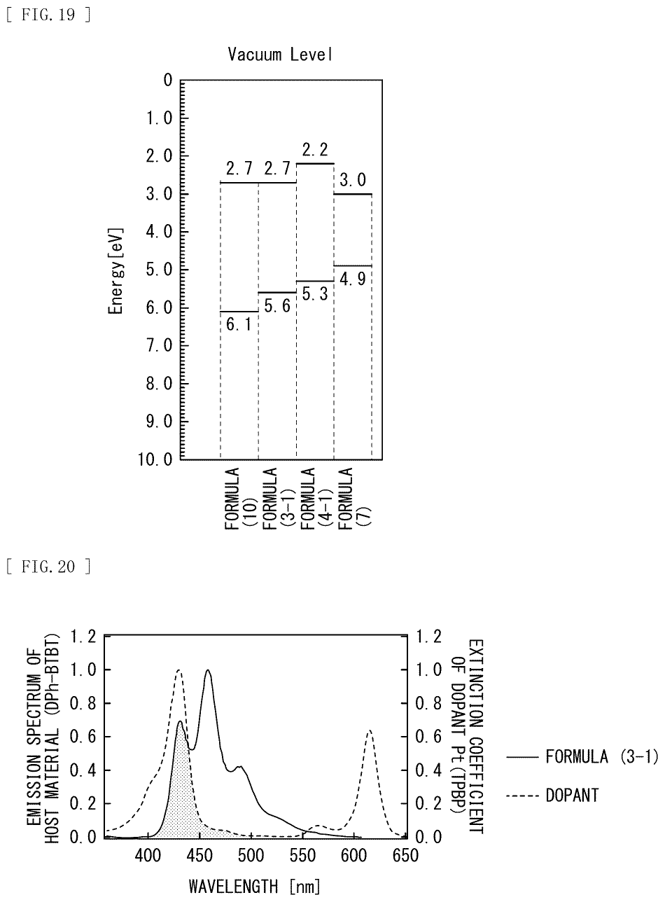

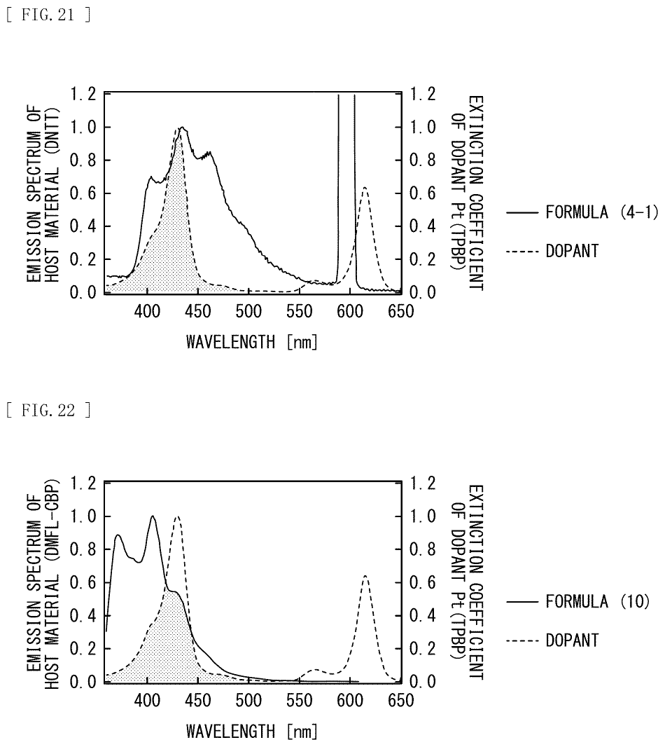

Preferably, the host material and the dopant material each have an energy level and a light emission property that allow for efficient energy transfer. For example, an energy gap of the dopant material preferably falls within an energy gap of the host material. Specifically, it is preferable that a HOMO level of the host material be 0.2 eV or more deeper than a HOMO level of the dopant material, and a LUMO level of the host material be 0.2 eV or more shallower than a LUMO level of the dopant material (see, for example, FIG. 19). In addition, an emission spectrum by photoexcitation or electroexcitation of the host material and an absorption spectrum of the dopant material preferably overlap each other (see, for example, FIGS. 20, 21, and 22).

In addition, the host material preferably has predetermined carrier mobility. For example, the host material preferably has mobility, which is measured by a space charge limited current (SCLC) method on a thin film thereof, of larger than 4E-5 cm²/Vs. Further, the host material preferably has mobility, which is measured by the space charge limited current (SCLC) method on the thin film thereof, of larger than 3E-3 cm²/Vs. Furthermore, the host material preferably has mobility, which is measured by the space charge limited current (SCLC) method on the thin film thereof, of larger than 6E-2 cm²/Vs.

Examples of the host material include a heteroacene derivative having, in a molecule, one skeleton represented by the general formula (1) or the general formula (2) below.

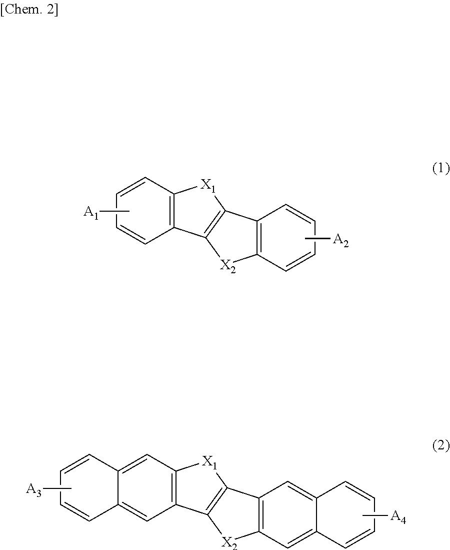

(X1 to X4 are each one of sulfur, oxygen, selenium, or tellurium; and A1 to A4 are each independently a hydrogen atom, an aryl group, a heteroaryl group, an alkyl group, an aryloxy group, a heteroaryloxy group, or an alkoxy group, or a derivative thereof.)

The aryl group and an aryl moiety of the aryloxy group described above are each, for example, one of a phenyl group, a biphenyl group, a naphthyl group, a naphthylphenyl group, a phenylnaphthyl group, a tolyl group, a xylyl group, a mesityl group, a terphenyl group, or a phenanthryl group that is unsubstituted or substituted by an alkyl group, an aryl group, or a heteroaryl group. The heteroaryl group and a heteroaryl moiety of the heteroaryloxy group described above are each selected from, for example, a thienyl group, a thiazolyl group, an isothiazolyl group, a furanyl group, an oxazolyl group, an oxadiazolyl group, an isoxazolyl group, a benzothienyl group, a benzofuranyl group, a pyridinyl group, a quinolinyl group, an isoquinolyl group, an acridinyl group, an indole group, an imidazole group, a benzimidazole group, a carbazolyl group, a dibenzofuranyl group, and a dibenzothiophenyl group that are unsubstituted or substituted by an alkyl group, an aryl group, or a heteroaryl group.

Examples of such a heteroacene material include compounds represented by a formula (1-1) to a formula (1-62) and a formula (2-1) to a formula (2-60) below.

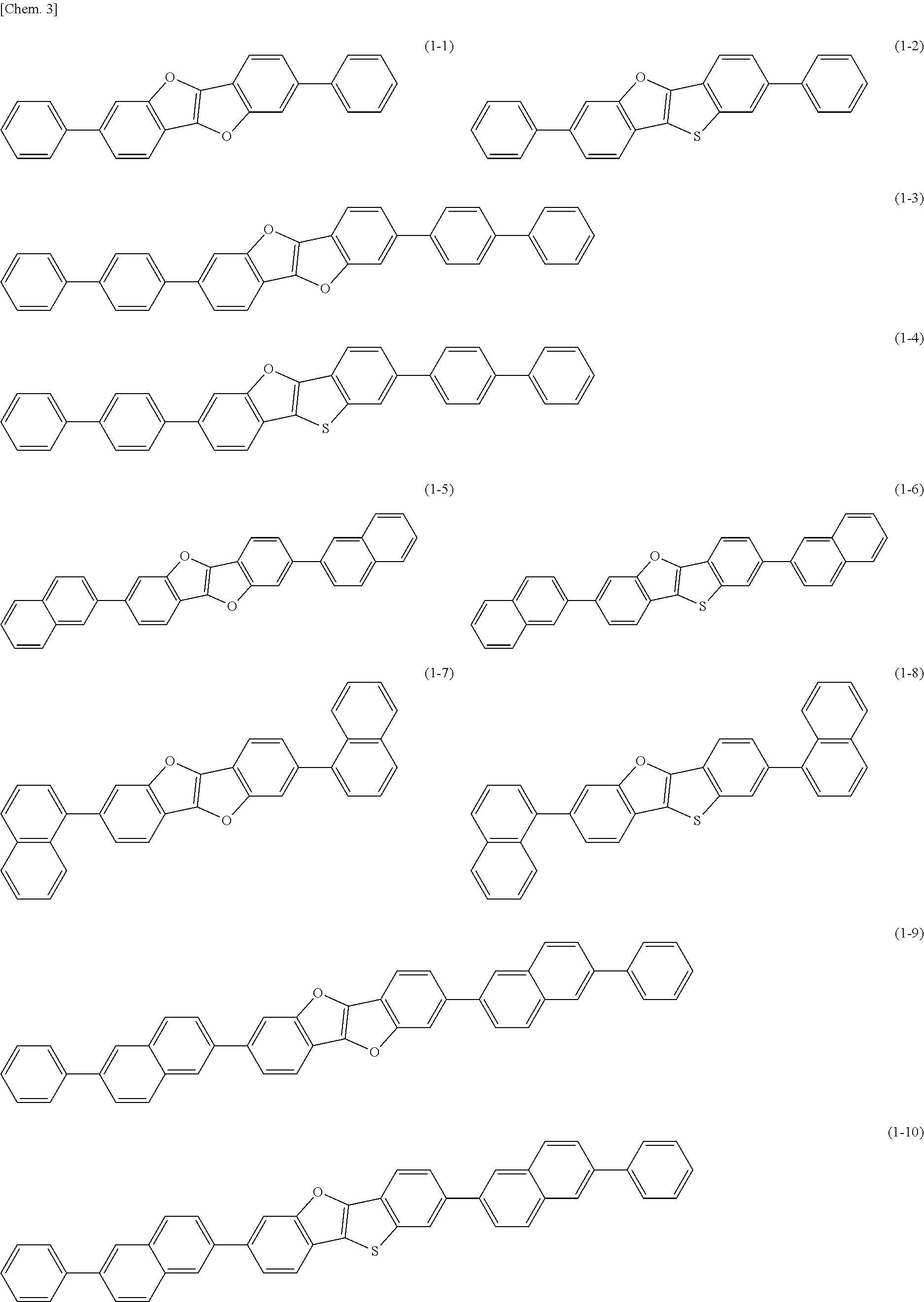

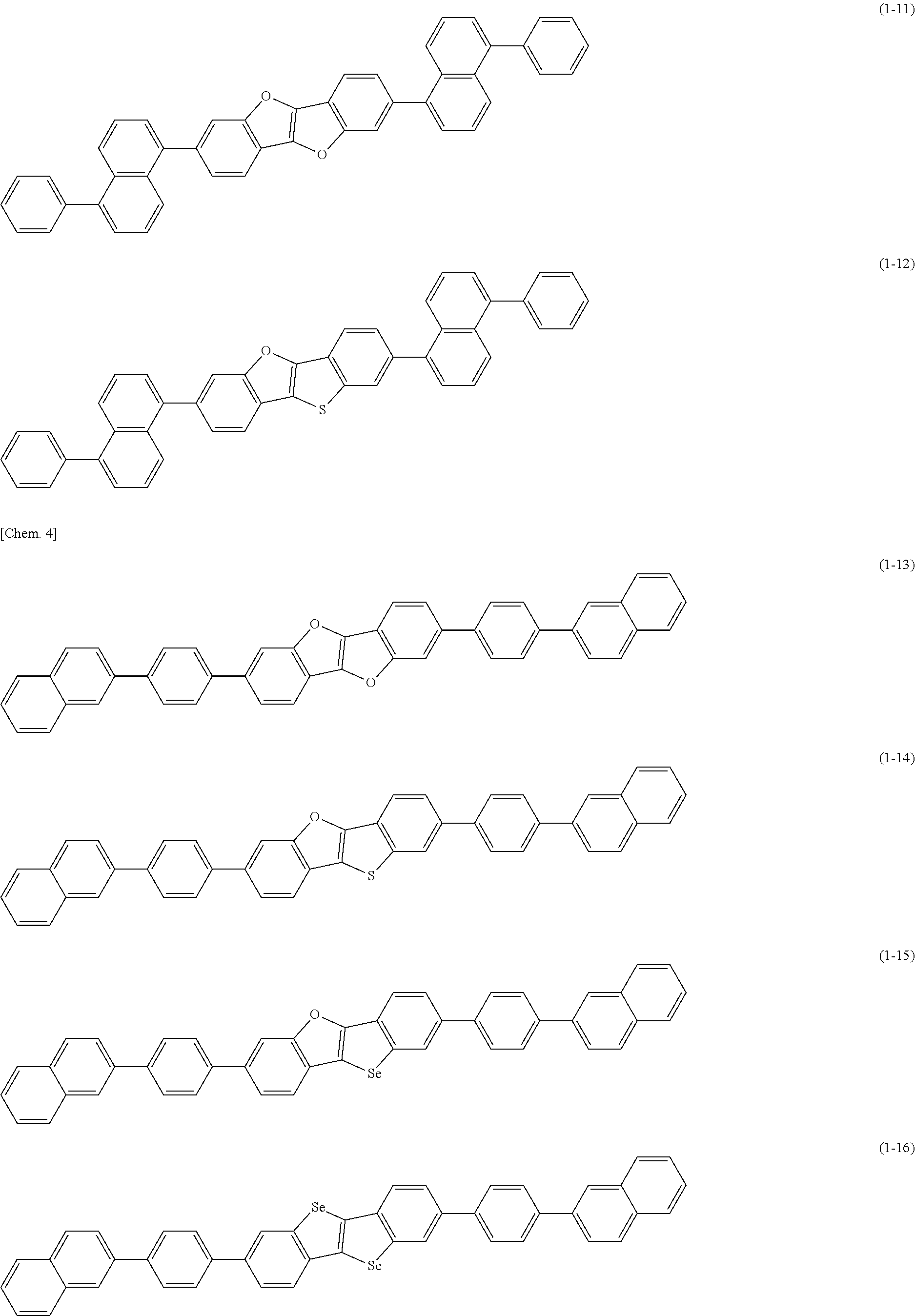

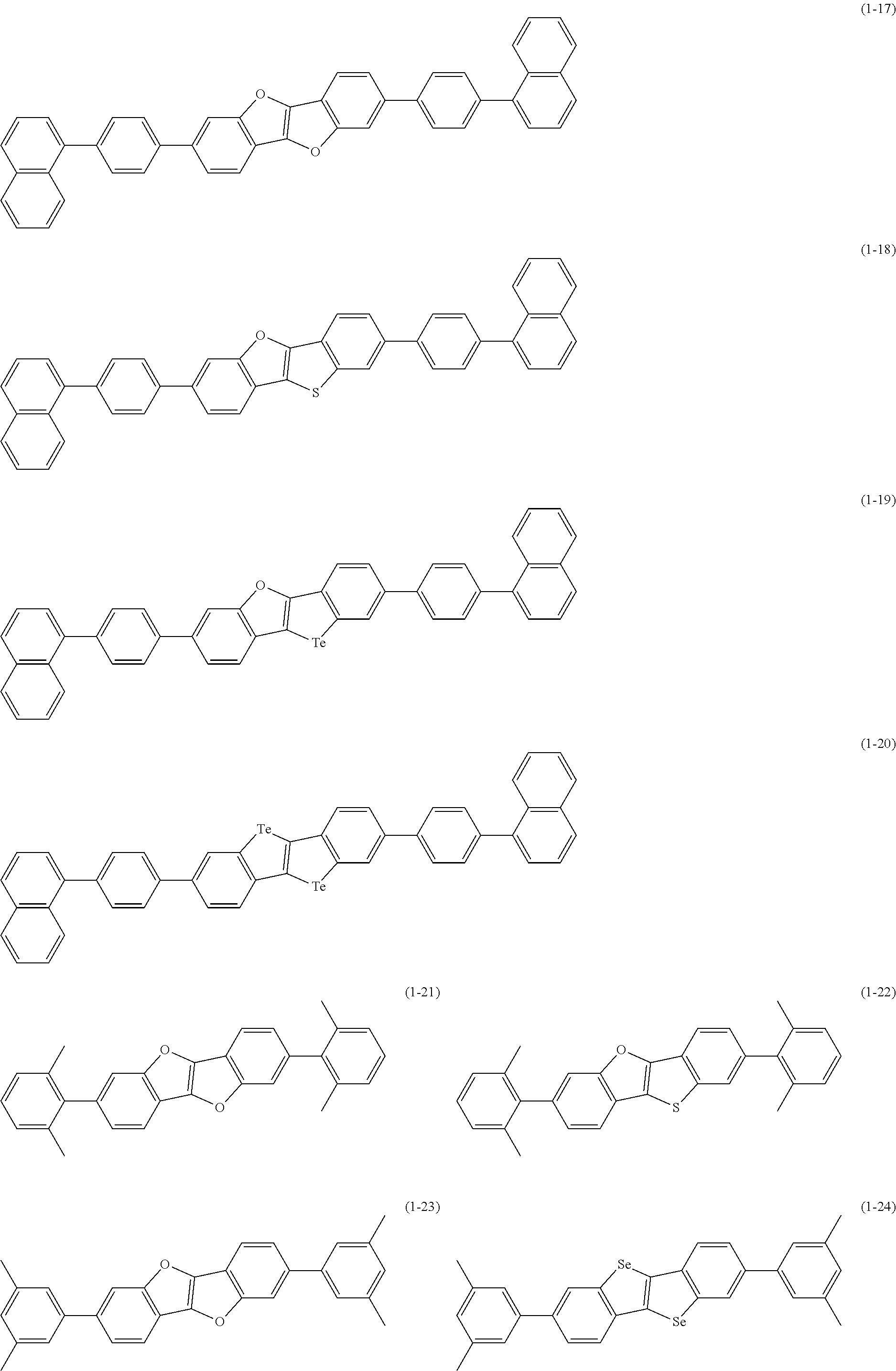

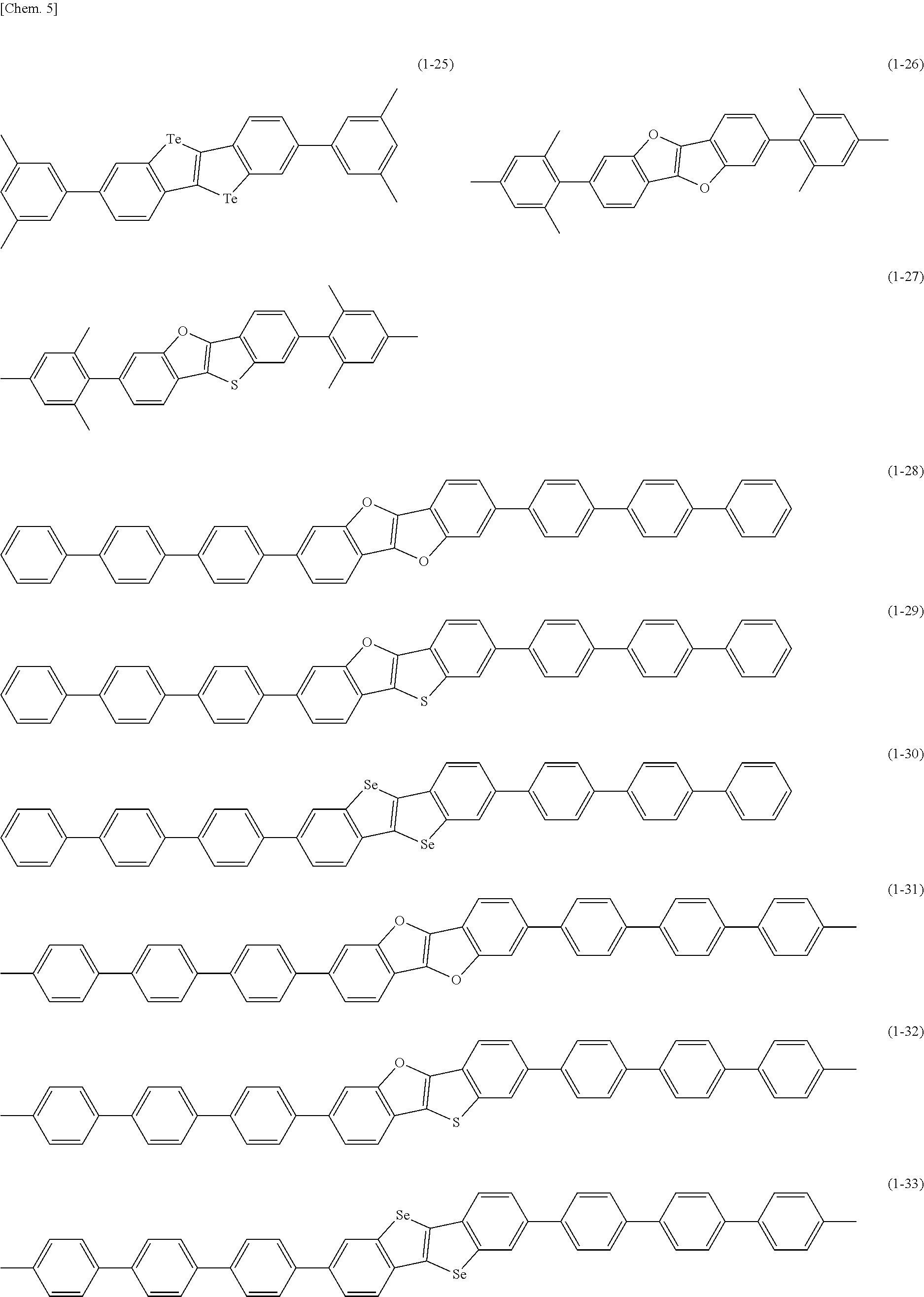

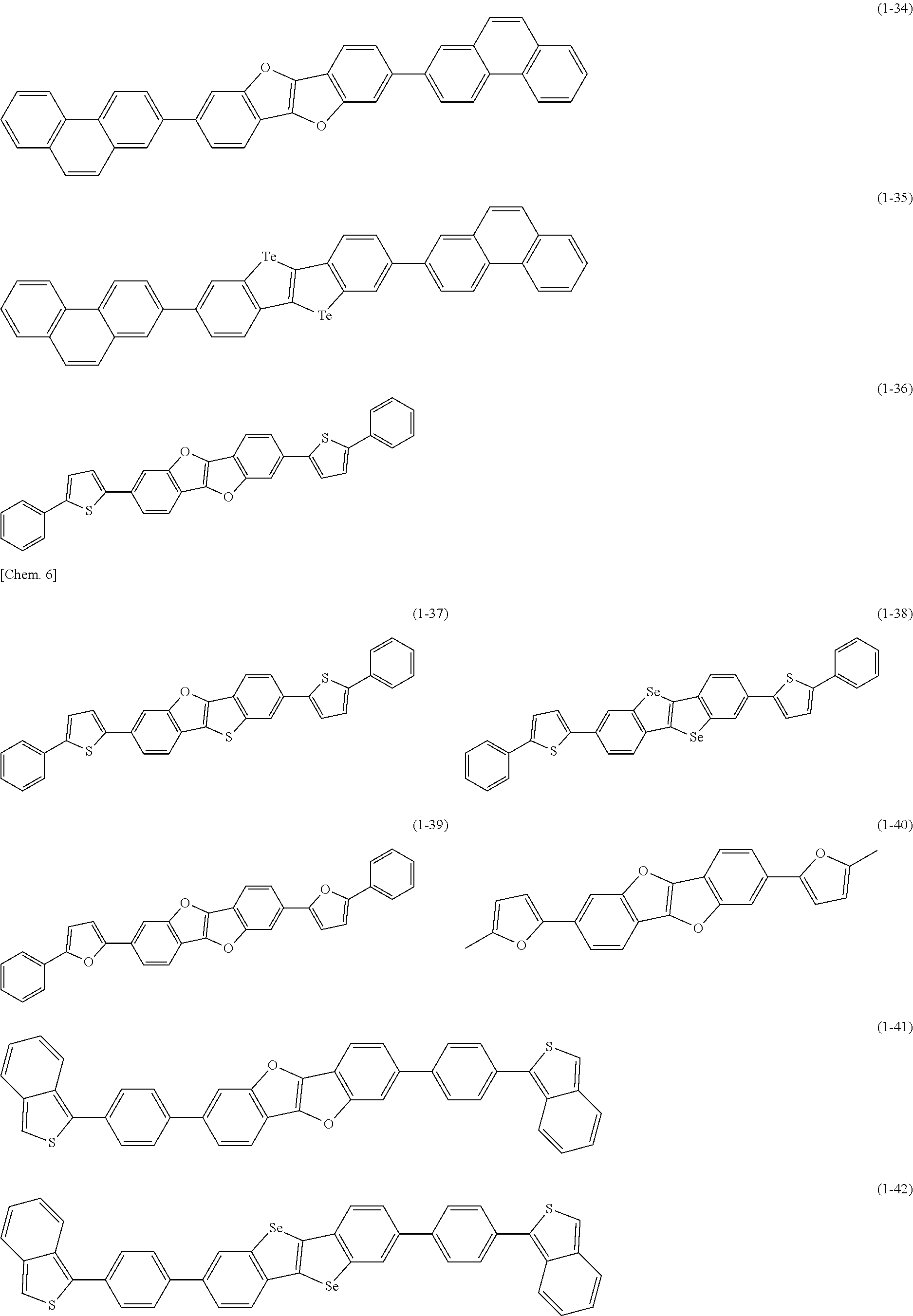

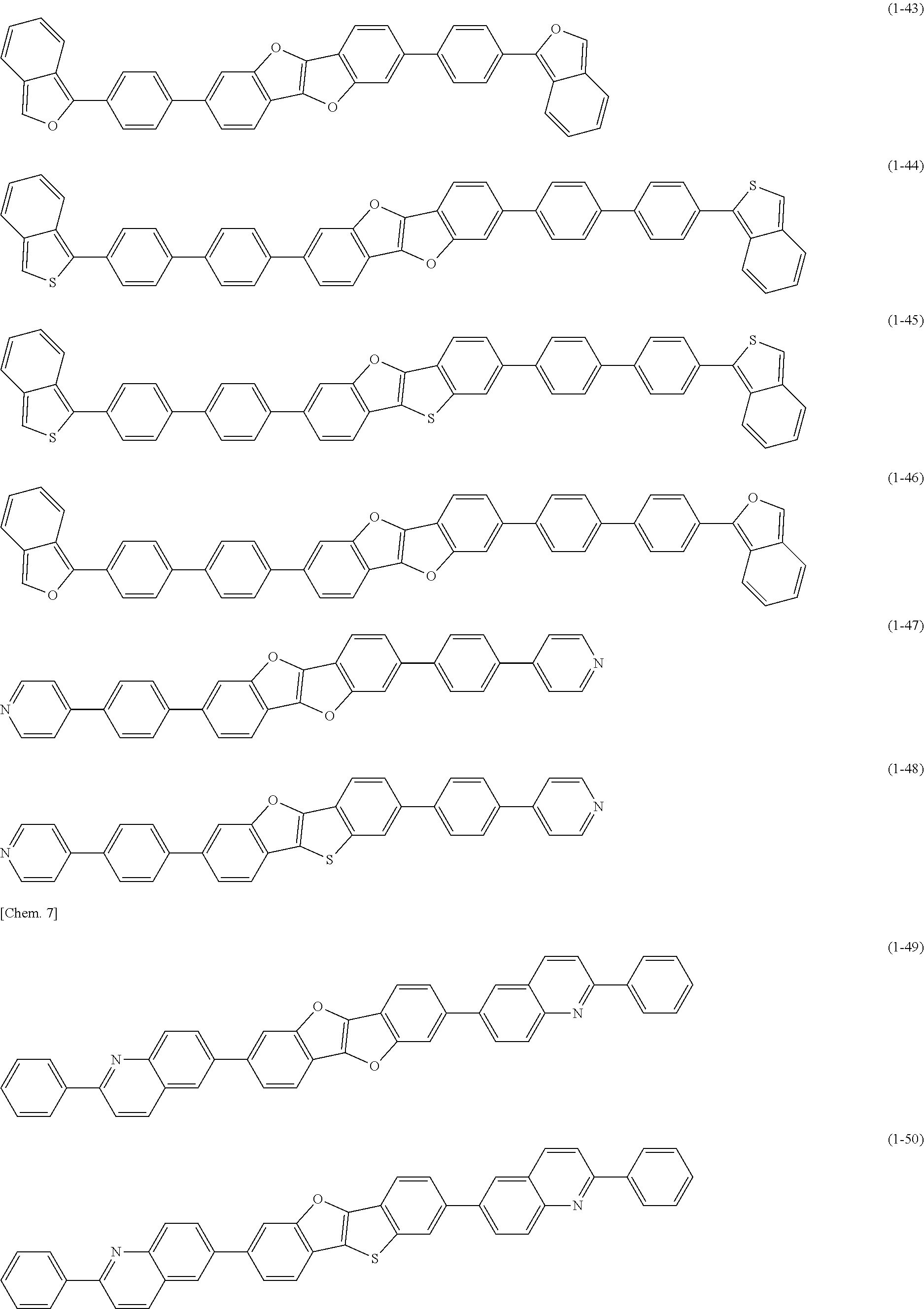

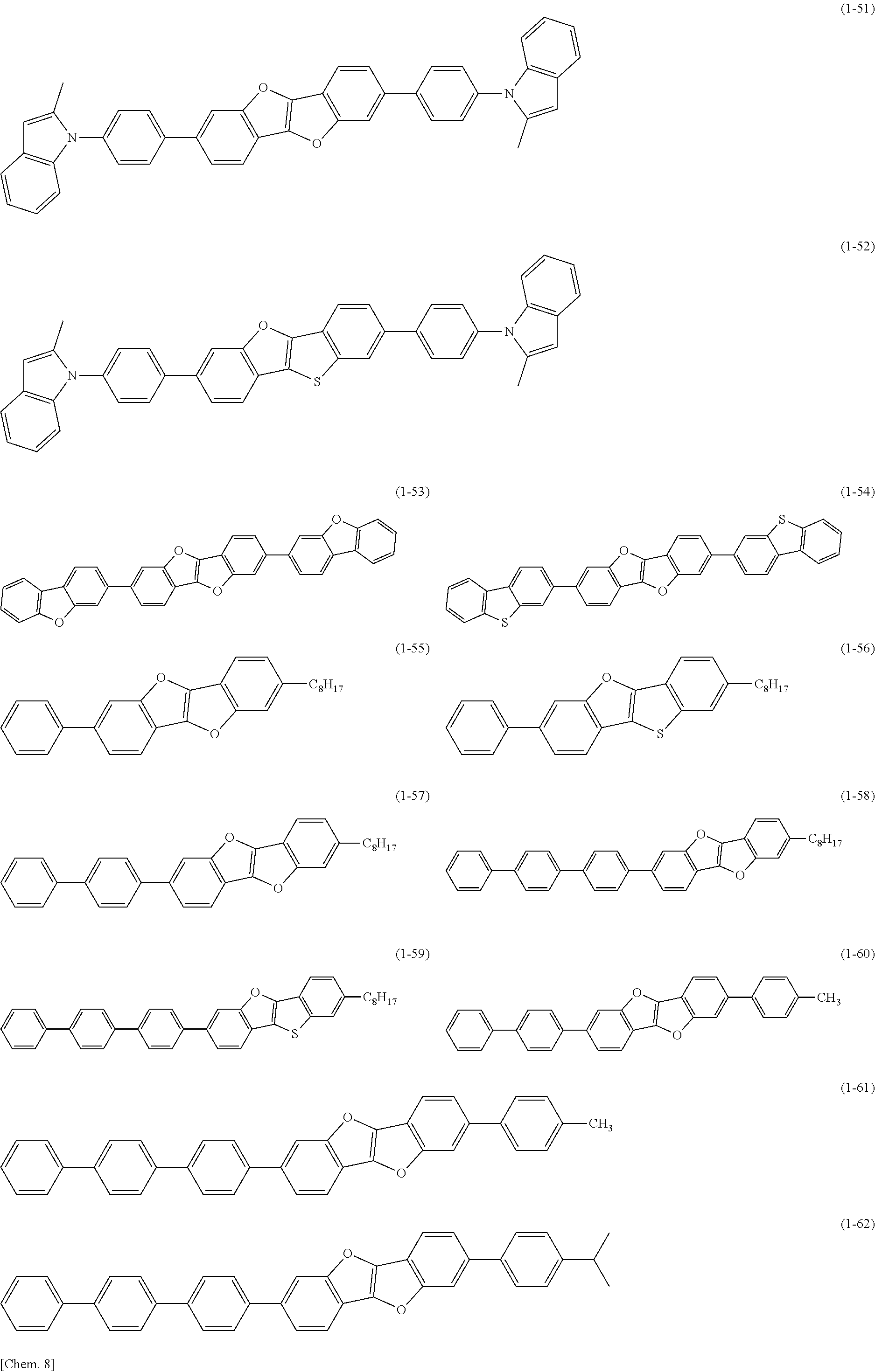

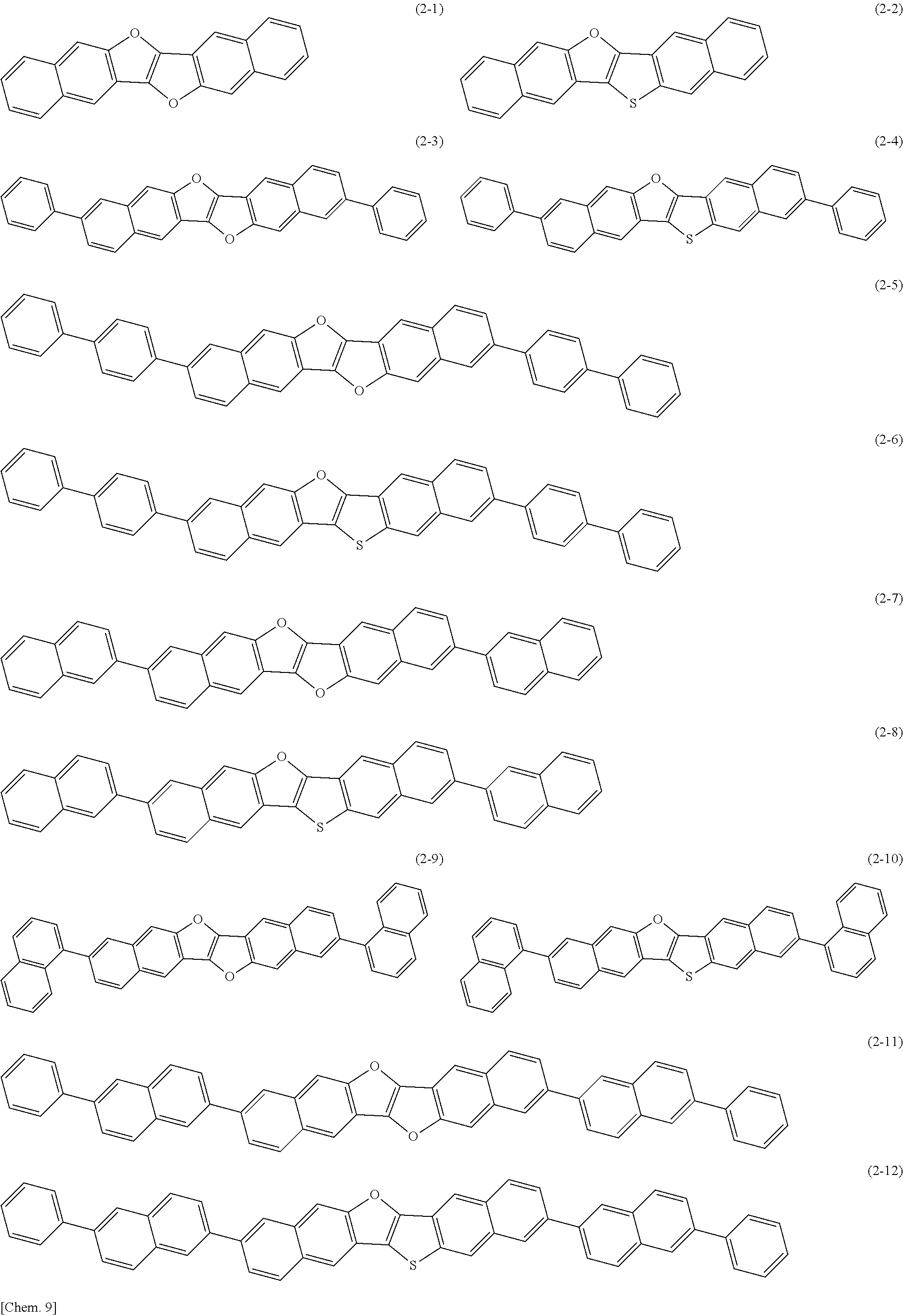

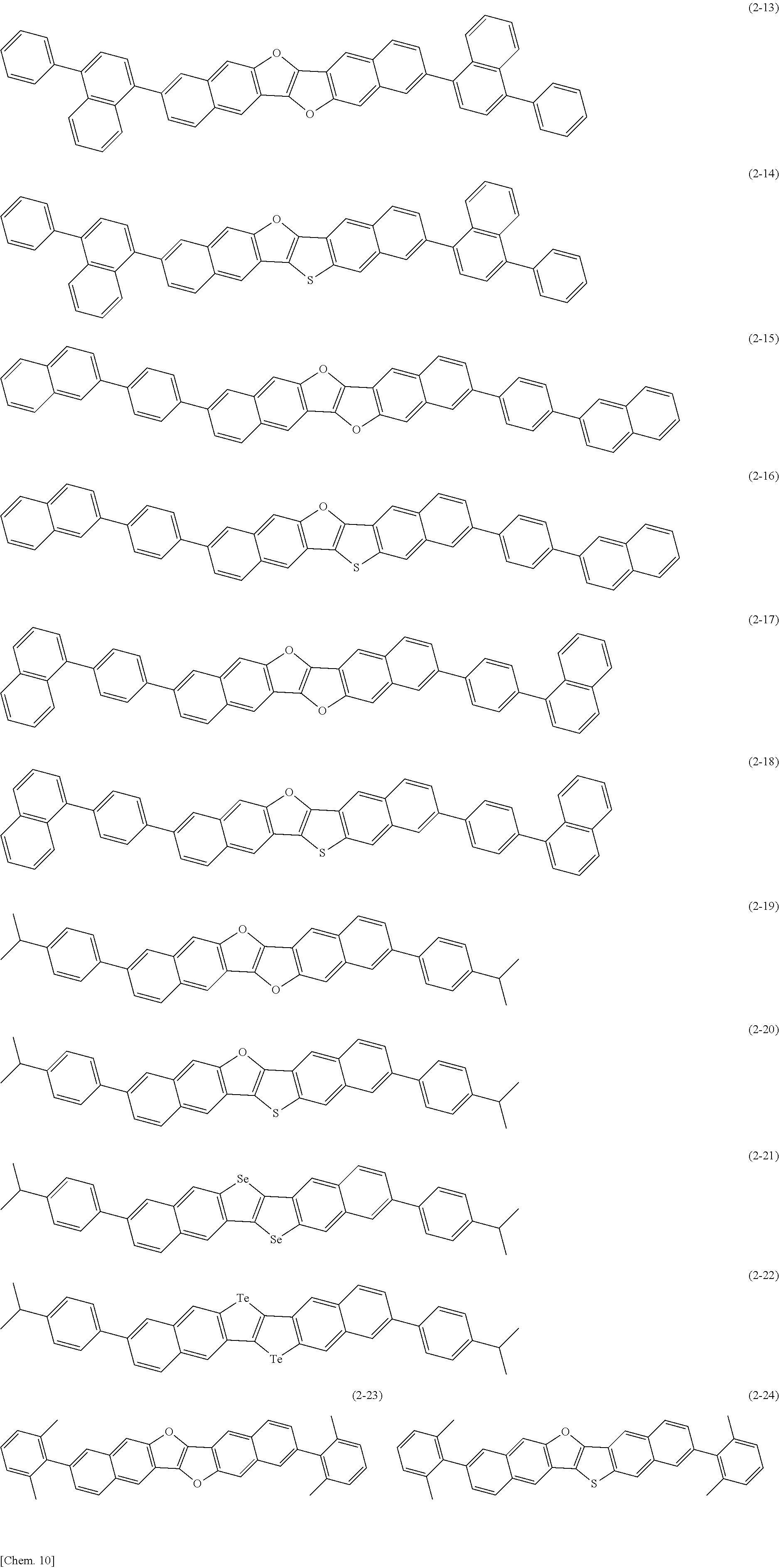

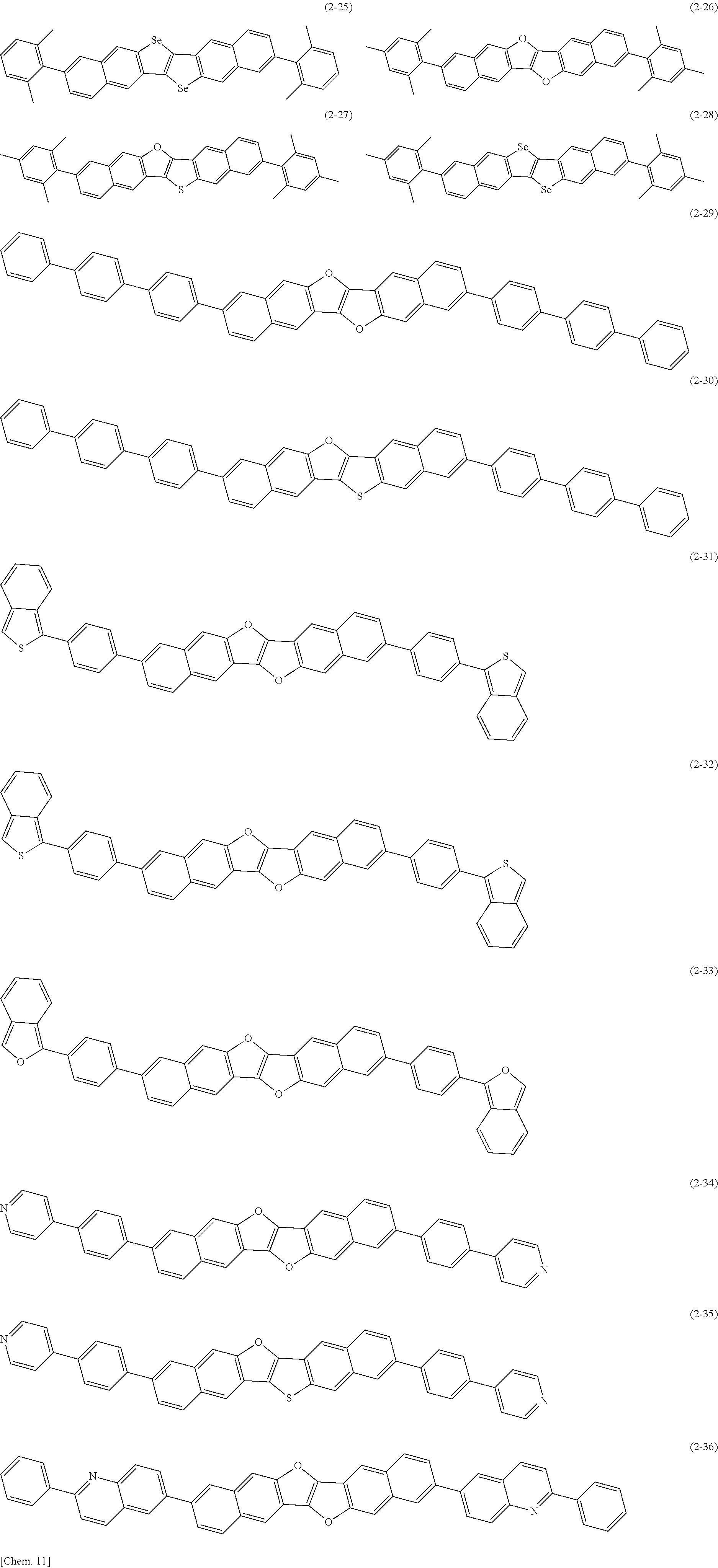

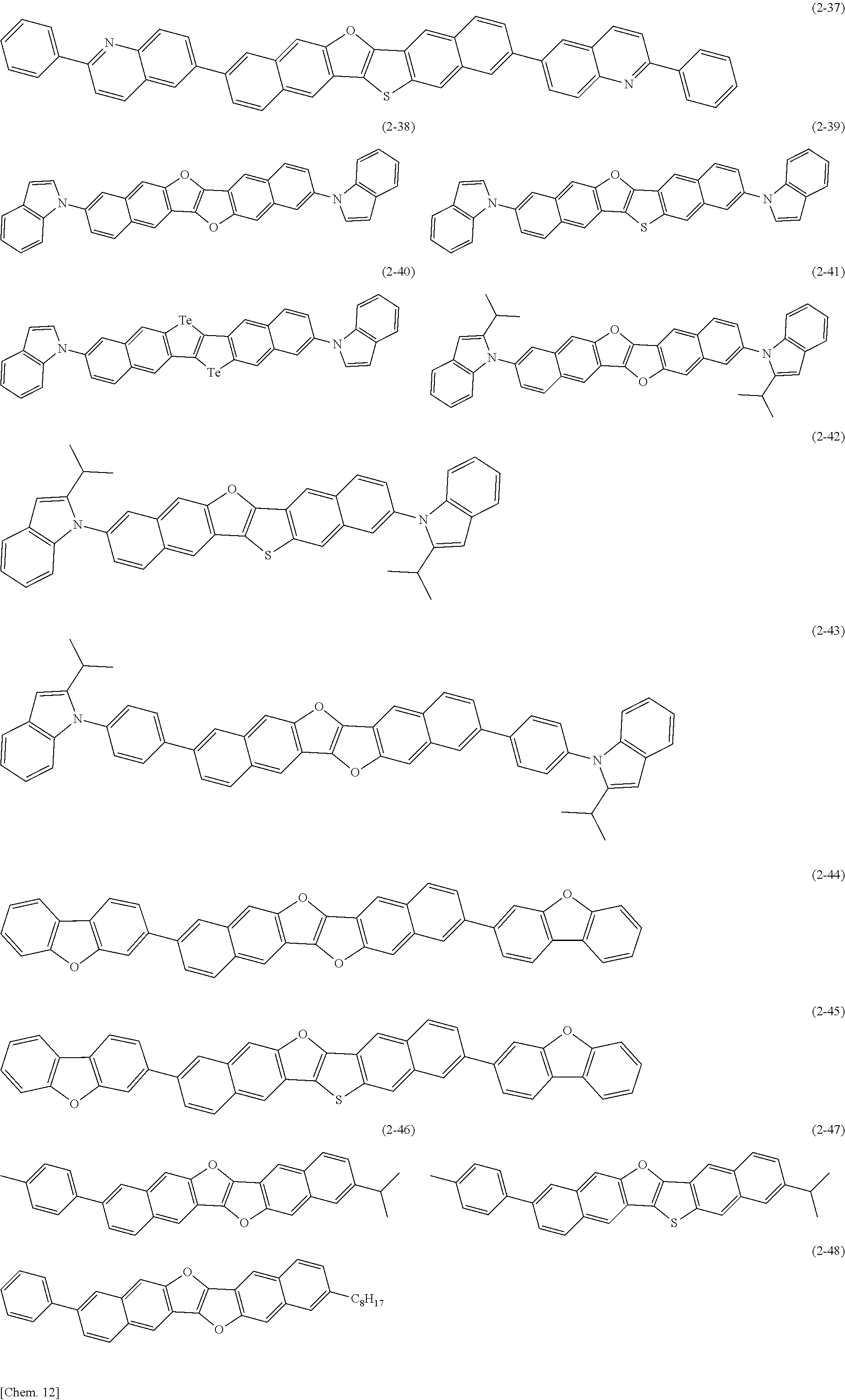

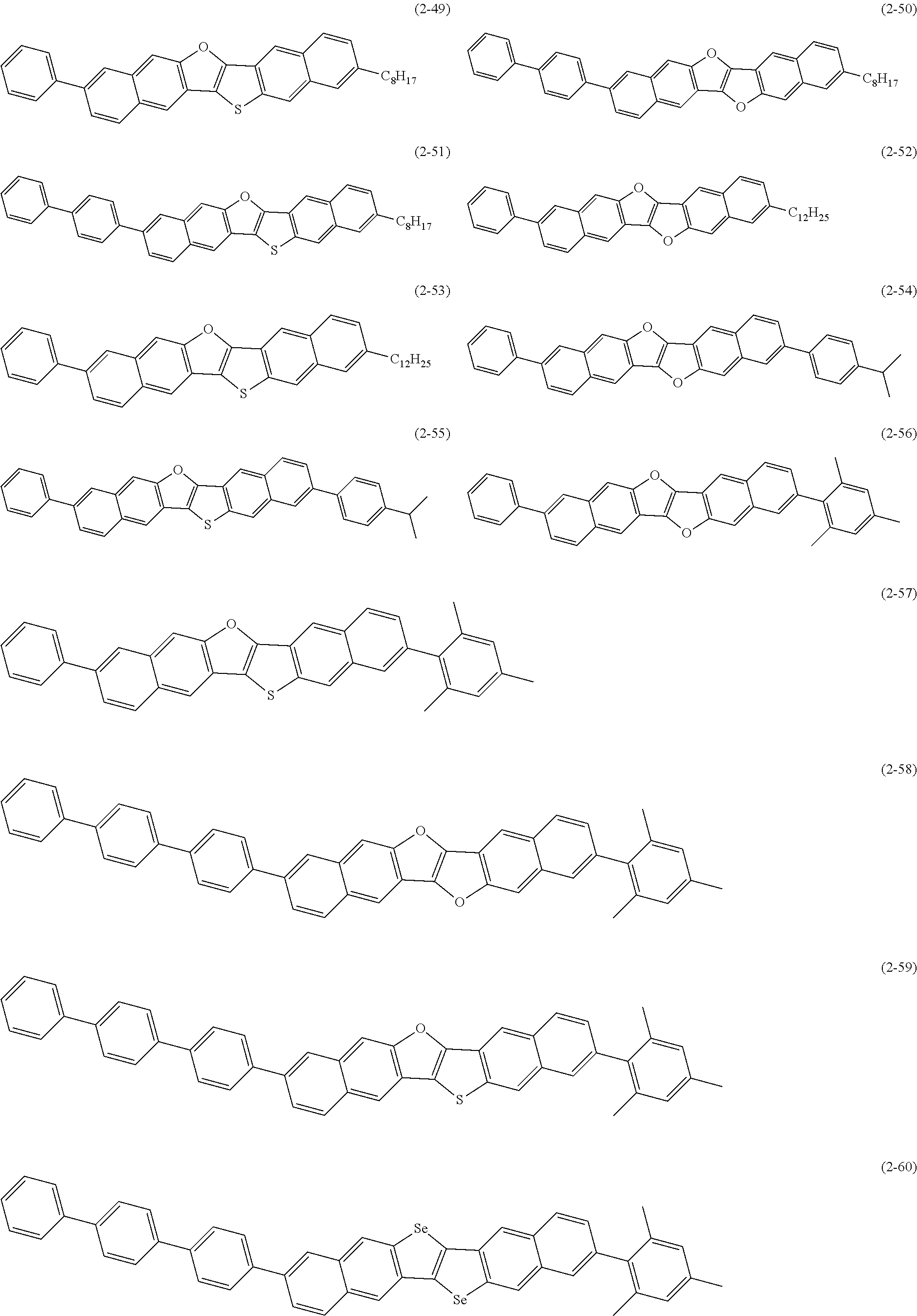

Further, among the heteroacene derivatives represented by the general formula (1) and the general formula (2) described above, it is preferable to use the benzothienobenzothiophene (BTBT) derivative represented by a general formula (3) and the dinaphthothienothiophene (DNTT) derivative represented by a general formula (4) below.

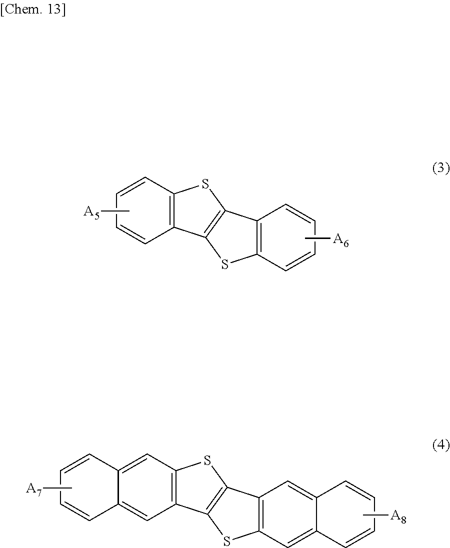

(A5 to A8 are each independently a hydrogen atom, an aryl group having 1 to 30 carbon atoms, a heteroaryl group having 1 to 30 carbon atoms, an alkyl group having 1 to 30 carbon atoms, an aryloxy group having 1 to 30 carbon atoms, a heteroaryloxy group having 1 to 30 carbon atoms, or an alkoxy group having 1 to 30 carbon atoms, or a derivative thereof.)

For example, the aryl group and an aryl moiety of the aryloxy group described above are each one of a phenyl group, a biphenyl group, a naphthyl group, a naphthylphenyl group, a phenylnaphthyl group, a tolyl group, a xylyl group, a mesityl group, a terphenyl group, or a phenanthryl group that is unsubstituted or substituted by an alkyl group, an aryl group, or a heteroaryl group. The heteroaryl group and a heteroaryl moiety of the heteroaryloxy group described above are each selected from a thienyl group, a thiazolyl group, an isothiazolyl group, a furanyl group, an oxazolyl group, an oxadiazolyl group, an isoxazolyl group, a benzothienyl group, a benzofuranyl group, a pyridinyl group, a quinolinyl group, an isoquinolyl group, an acridinyl group, an indole group, an imidazole group, a benzimidazole group, a carbazolyl group, a dibenzofuranyl group, and a dibenzothiophenyl group that are unsubstituted or substituted by an alkyl group, an aryl group, or a heteroaryl group.

Examples of such a BTBT derivative include compounds represented by a formula (3-1) to a formula (3-52) below. Examples of the DNTT derivative include compounds represented by a formula (4-1) to a formula (4-53) below.

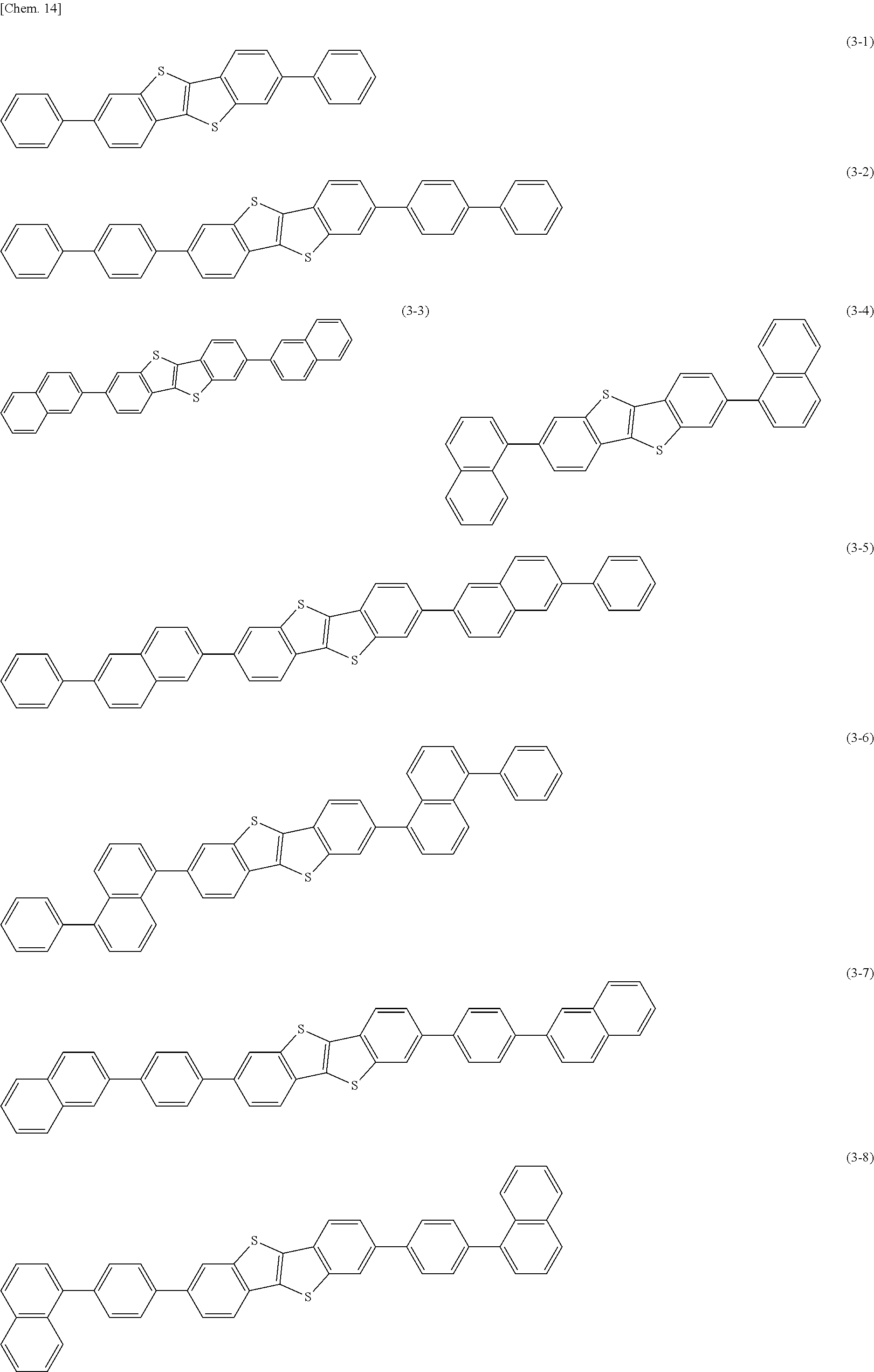

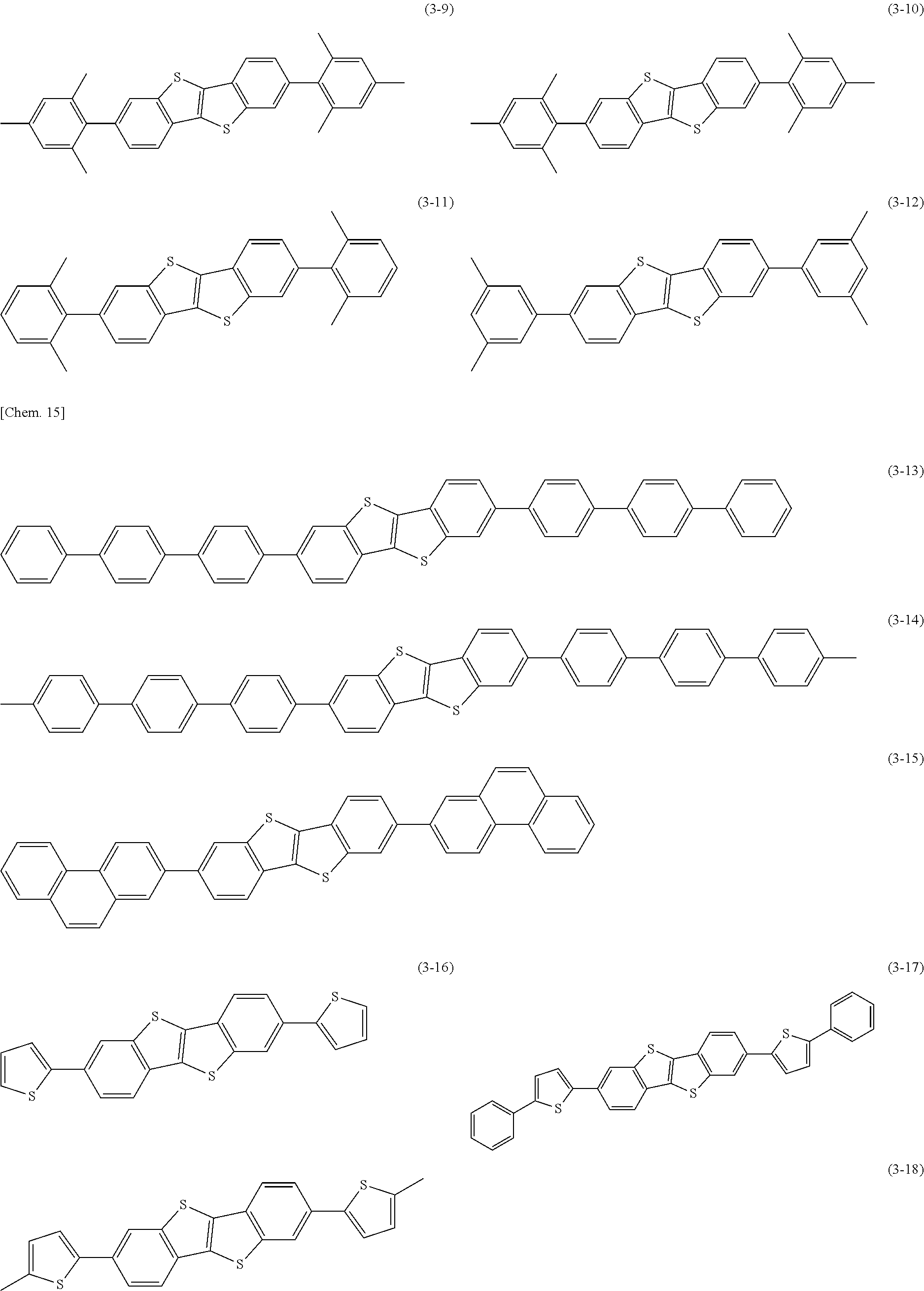

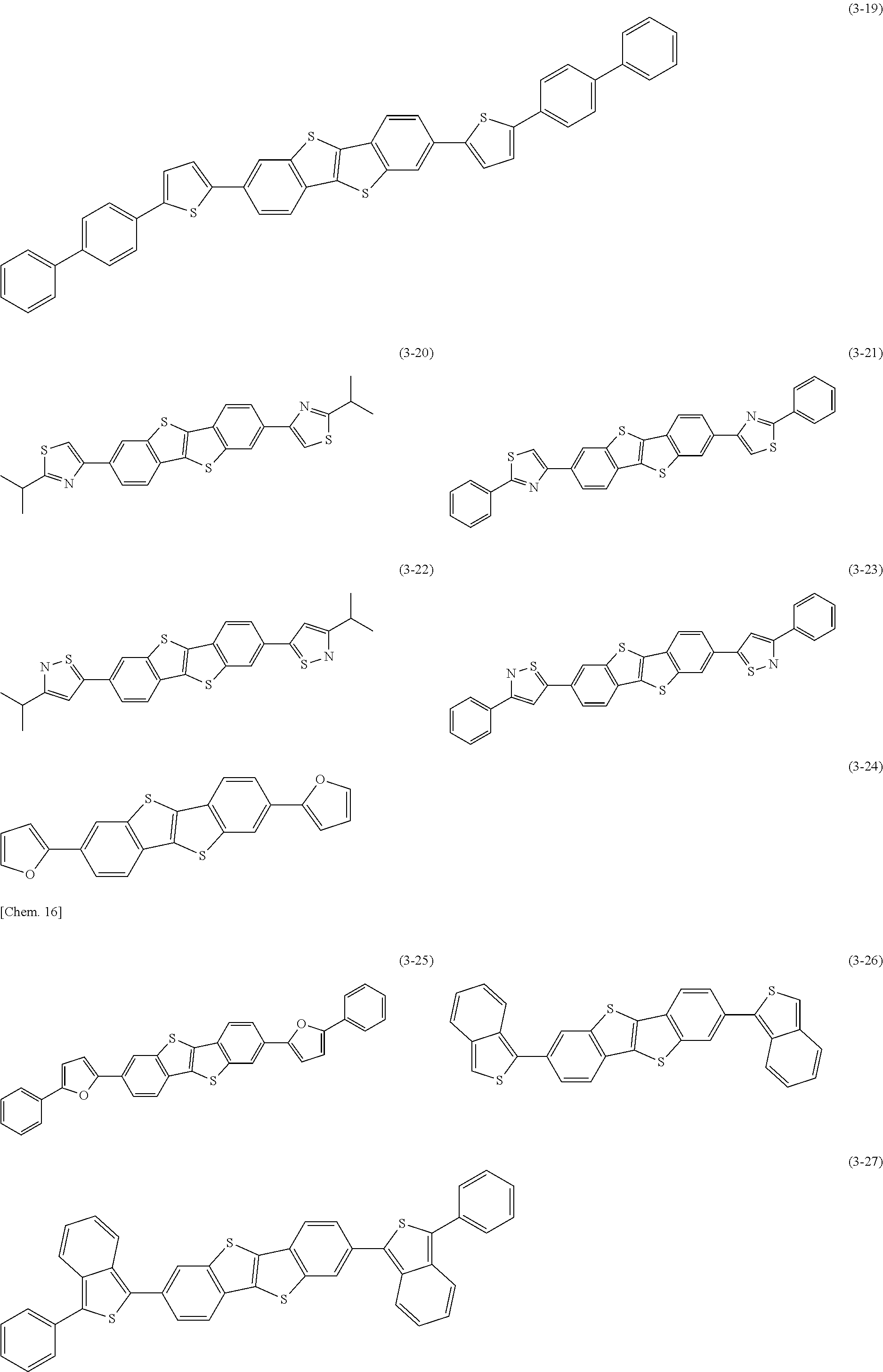

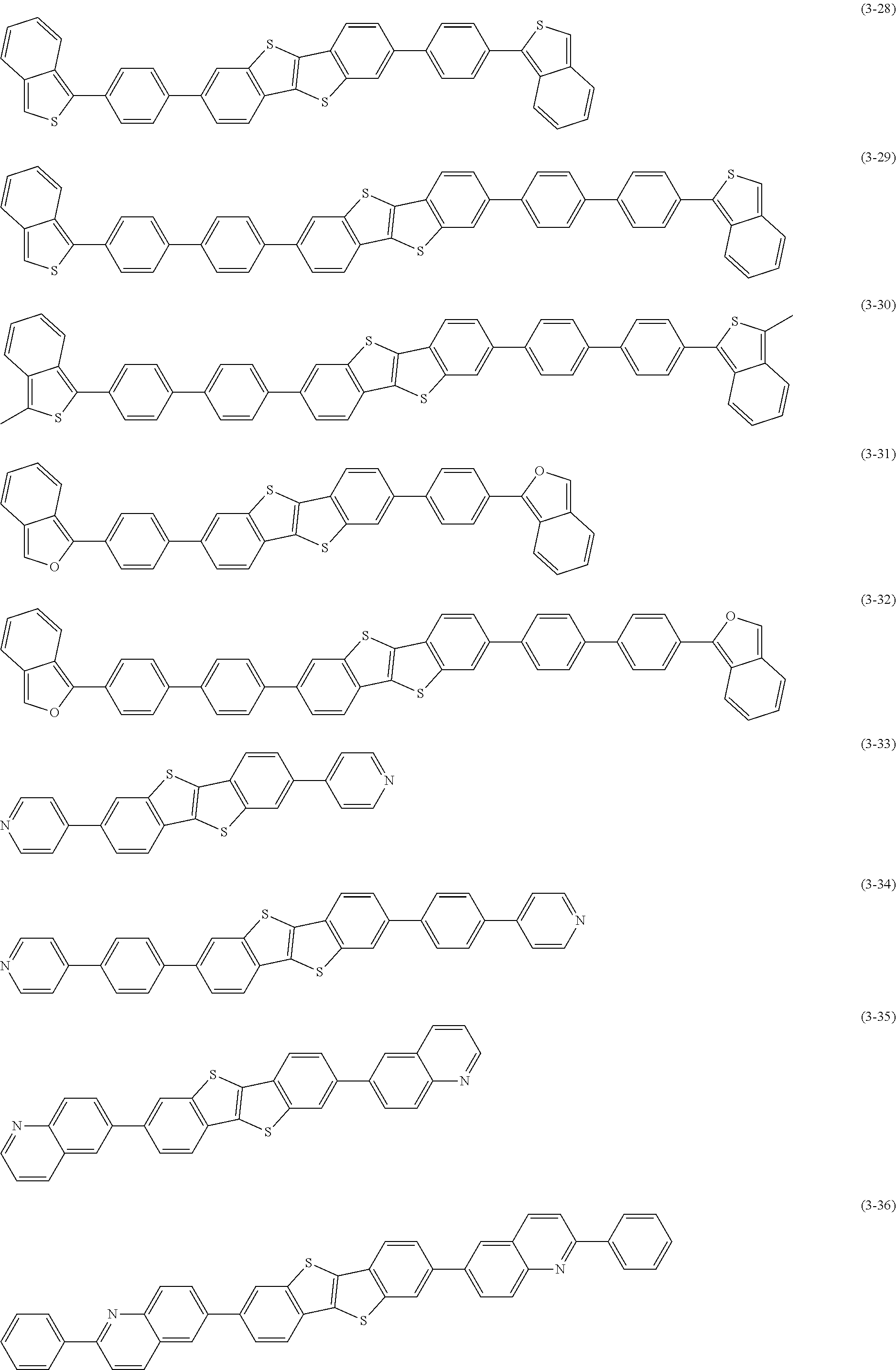

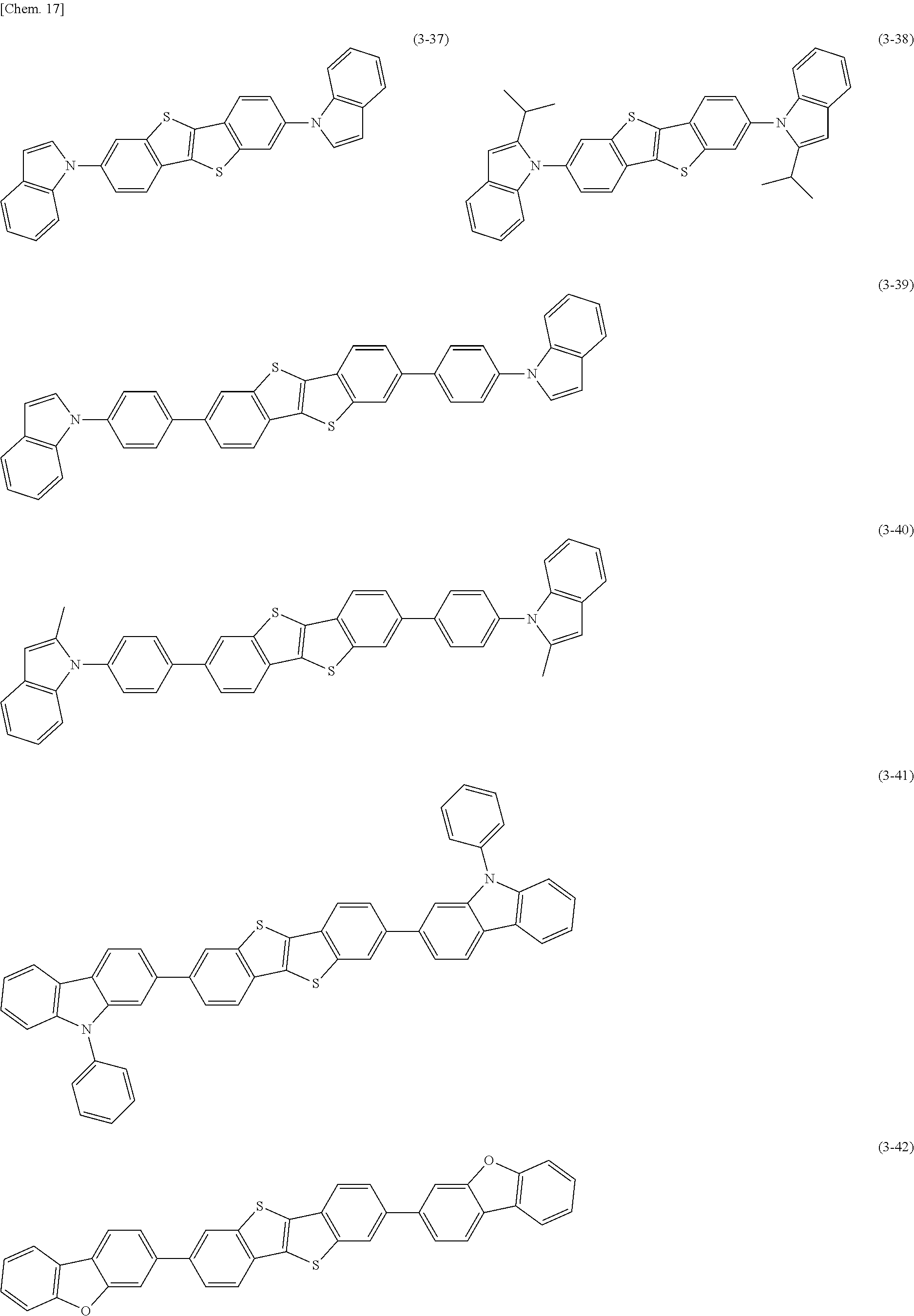 [SMILES: c1ccc2c(c1)ccn2-c1ccc2c(c1)sc1c3ccc(-n4ccc5ccccc54)cc3sc21 ; CC(C)c1cc2ccccc2n1-c1ccc2c(c1)sc1c3ccc(-n4c(C(C)C)cc5ccccc54)cc3sc21 ; c1ccc2c(c1)ccn2-c1ccc(-c2ccc3c(c2)sc2c4ccc(-c5ccc(-n6ccc7ccccc76)cc5)cc4sc32)cc1 ; Cc1cc2ccccc2n1-c1ccc(-c2ccc3c(c2)sc2c4ccc(-c5ccc(-n6c(C)cc7ccccc76)cc5)cc4sc32)cc1 ; c1ccc(-n2c3ccccc3c3ccc(-c4ccc5c(c4)sc4c6ccc(-c7ccc8c9ccccc9n(-c9ccccc9)c8c7)cc6sc54)cc32)cc1 ; c1ccc2c(c1)oc1cc(-c3ccc4c(c3)sc3c5ccc(-c6ccc7c(c6)oc6ccccc67)cc5sc43)ccc12]

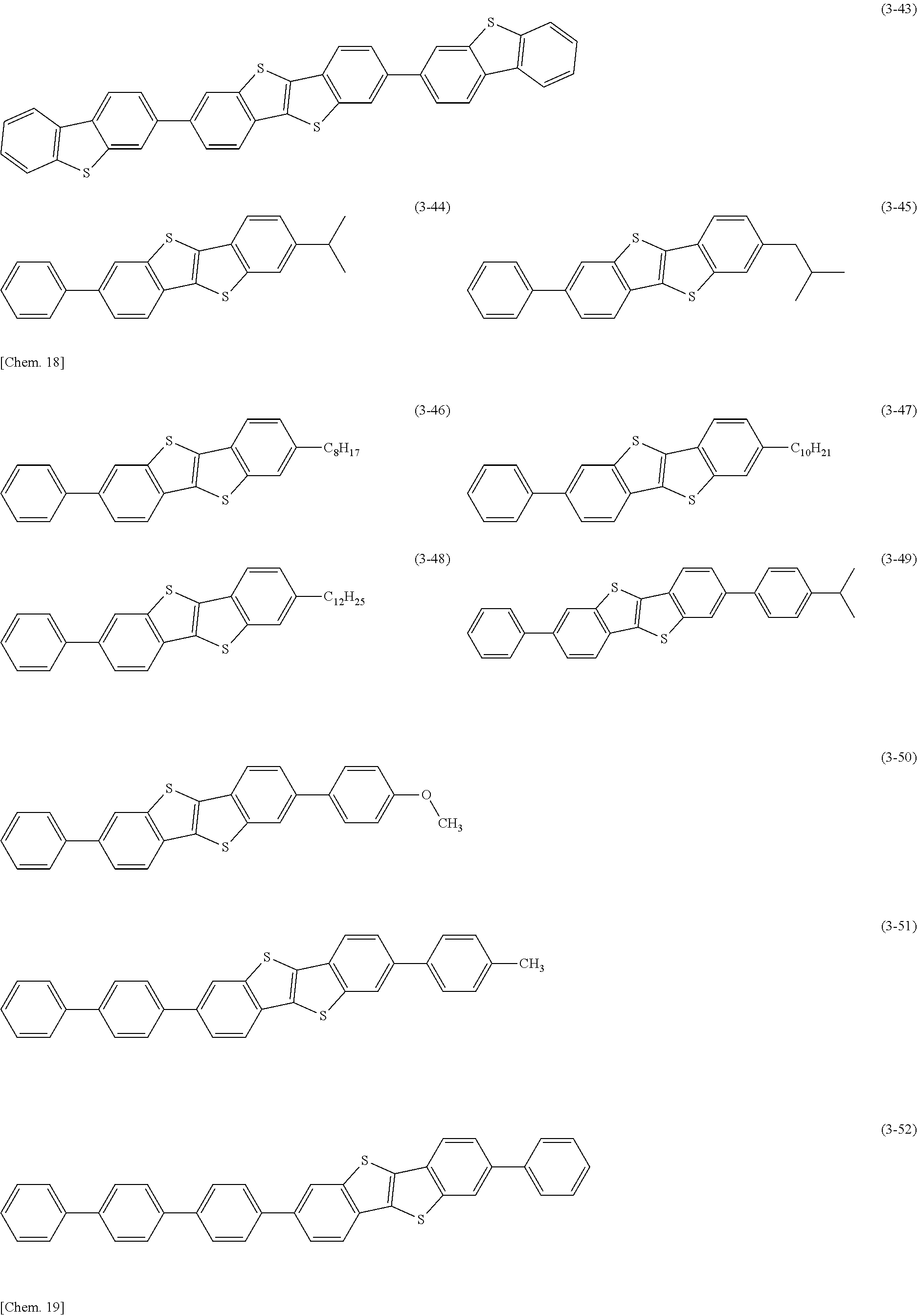

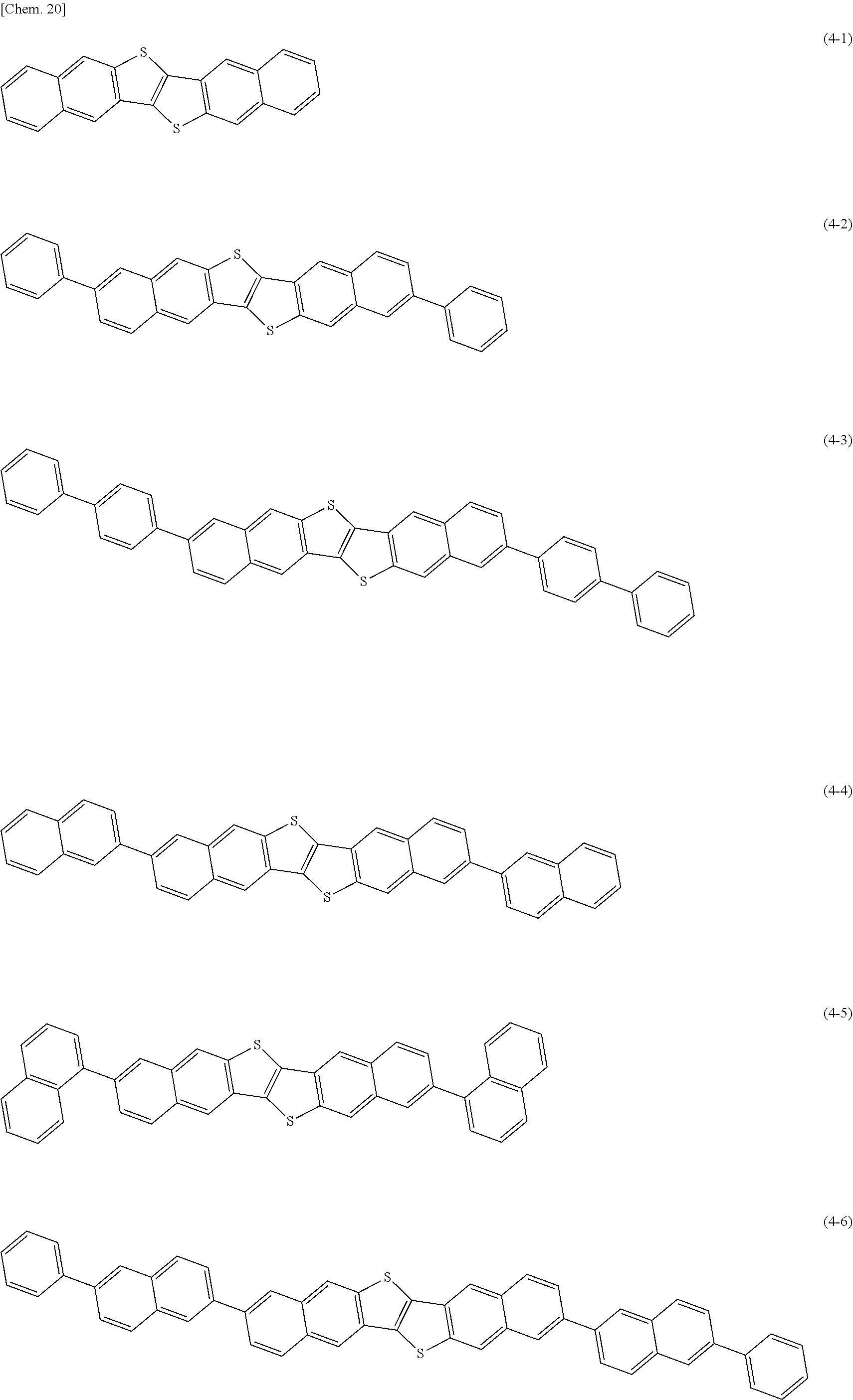 [SMILES: c1ccc2cc3c(cc2c1)sc1c2cc4ccccc4cc2sc31 ; c1ccc(-c2ccc3cc4c(cc3c2)sc2c3cc5ccc(-c6ccccc6)cc5cc3sc42)cc1 ; c1ccc(-c2ccc(-c3ccc4cc5c(cc4c3)sc3c4cc6ccc(-c7ccc(-c8ccccc8)cc7)cc6cc4sc53)cc2)cc1 ; c1ccc2cc(-c3ccc4cc5c(cc4c3)sc3c4cc6ccc(-c7ccc8ccccc8c7)cc6cc4sc53)ccc2c1 ; c1ccc2c(-c3ccc4cc5c(cc4c3)sc3c4cc6ccc(-c7cccc8ccccc78)cc6cc4sc53)cccc2c1 ; c1ccc(-c2ccc3cc(-c4ccc5cc6c(cc5c4)sc4c5cc7ccc(-c8ccc9cc(-c%10ccccc%10)ccc9c8)cc7cc5sc64)ccc3c2)cc1]

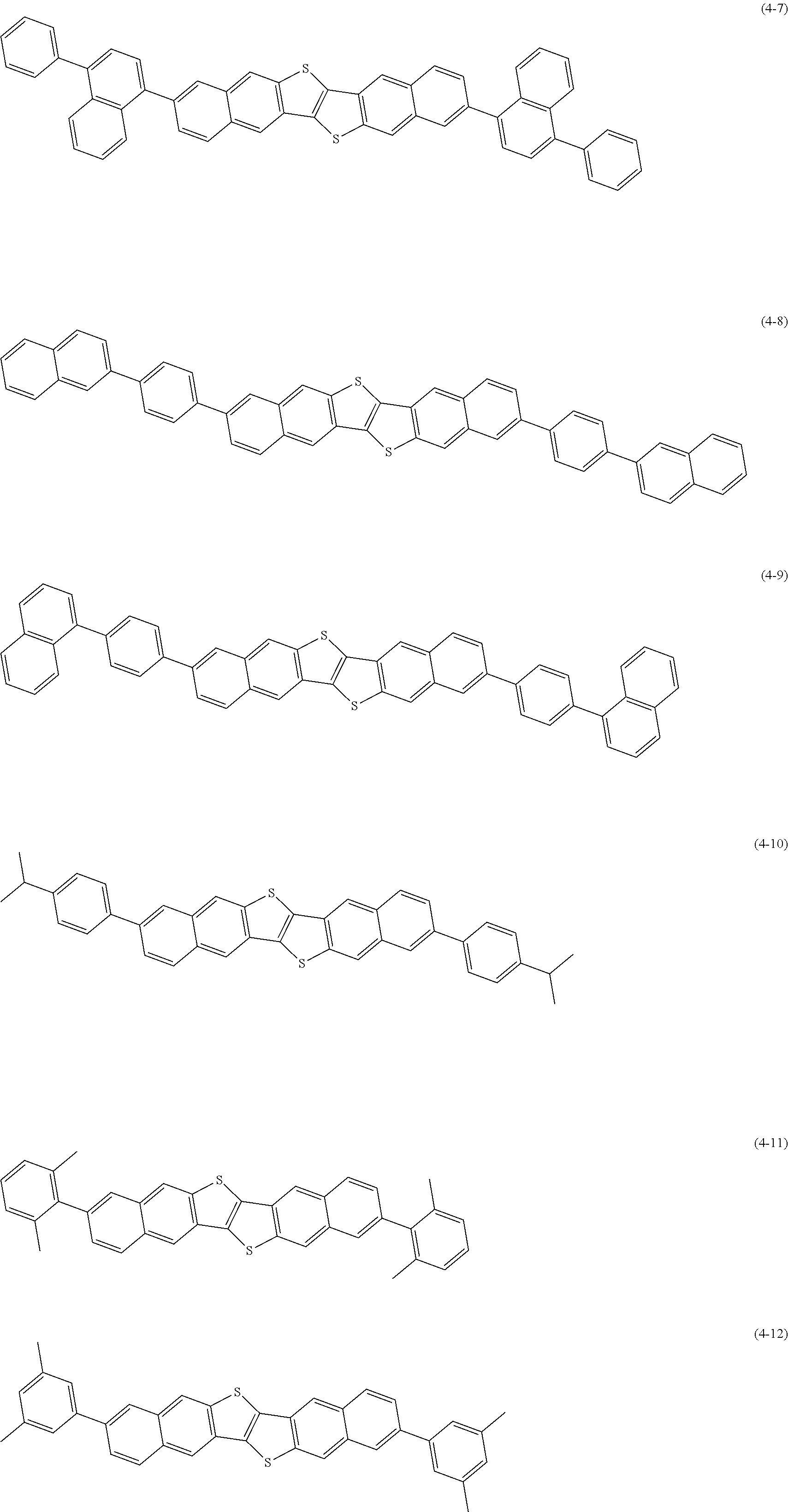

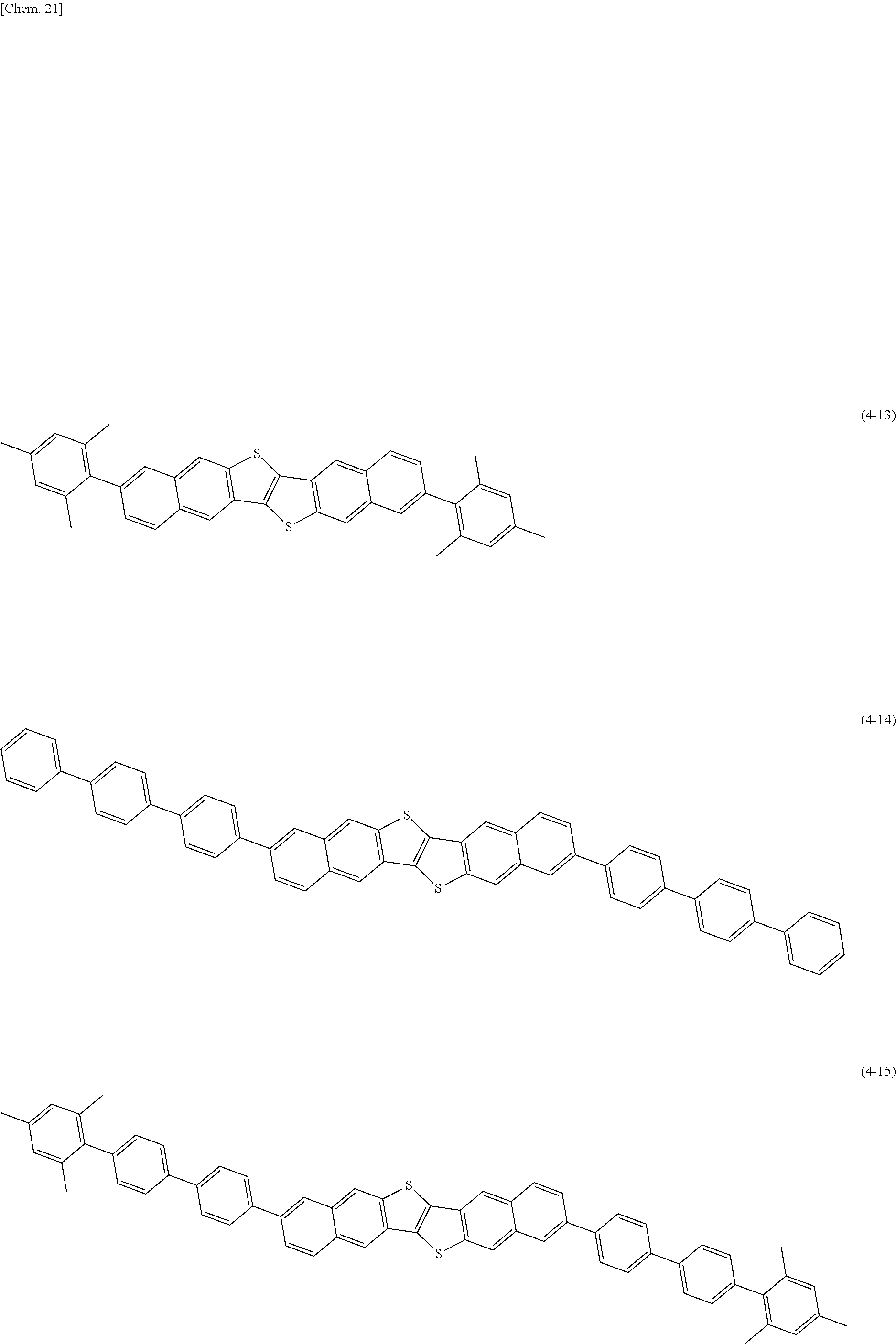

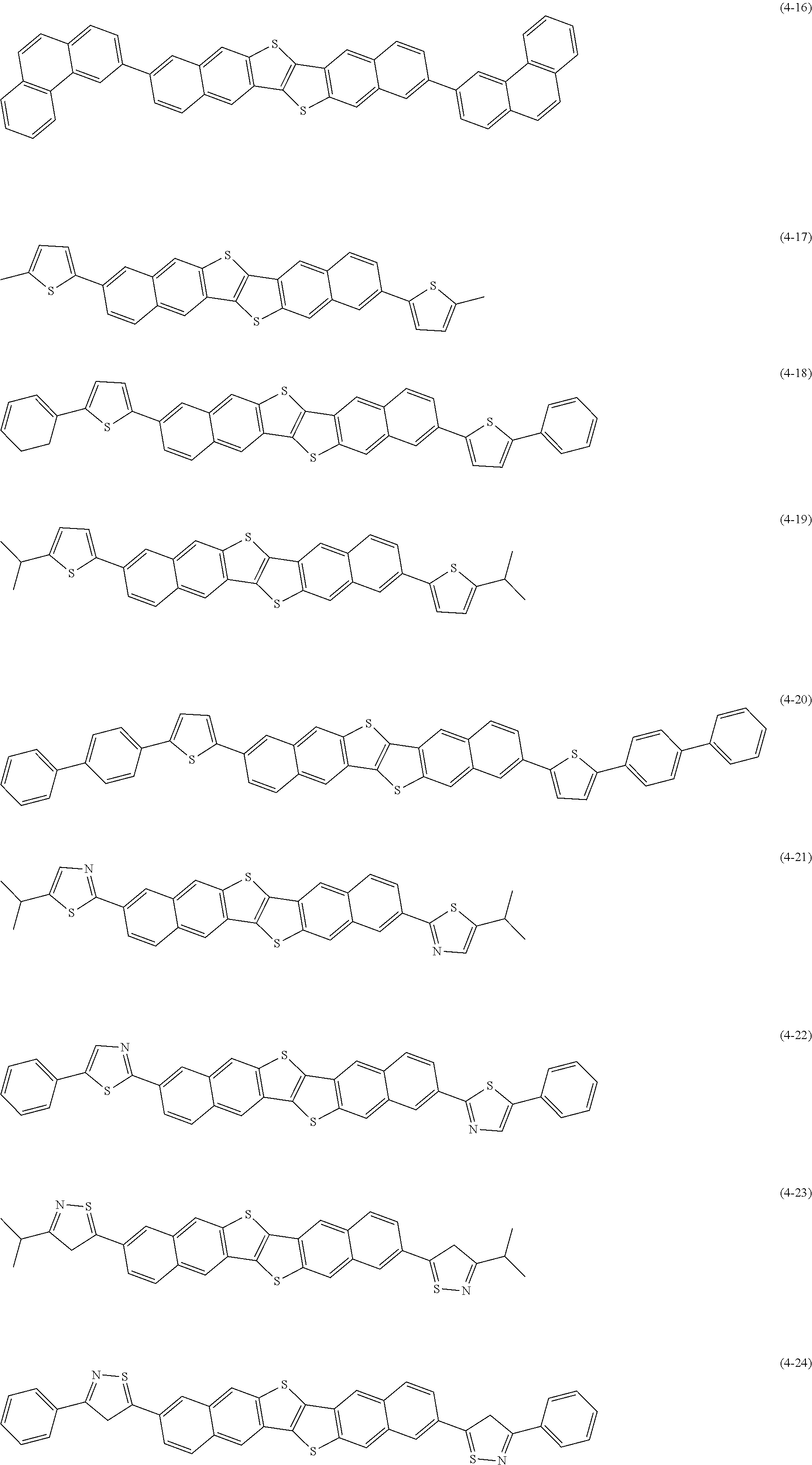

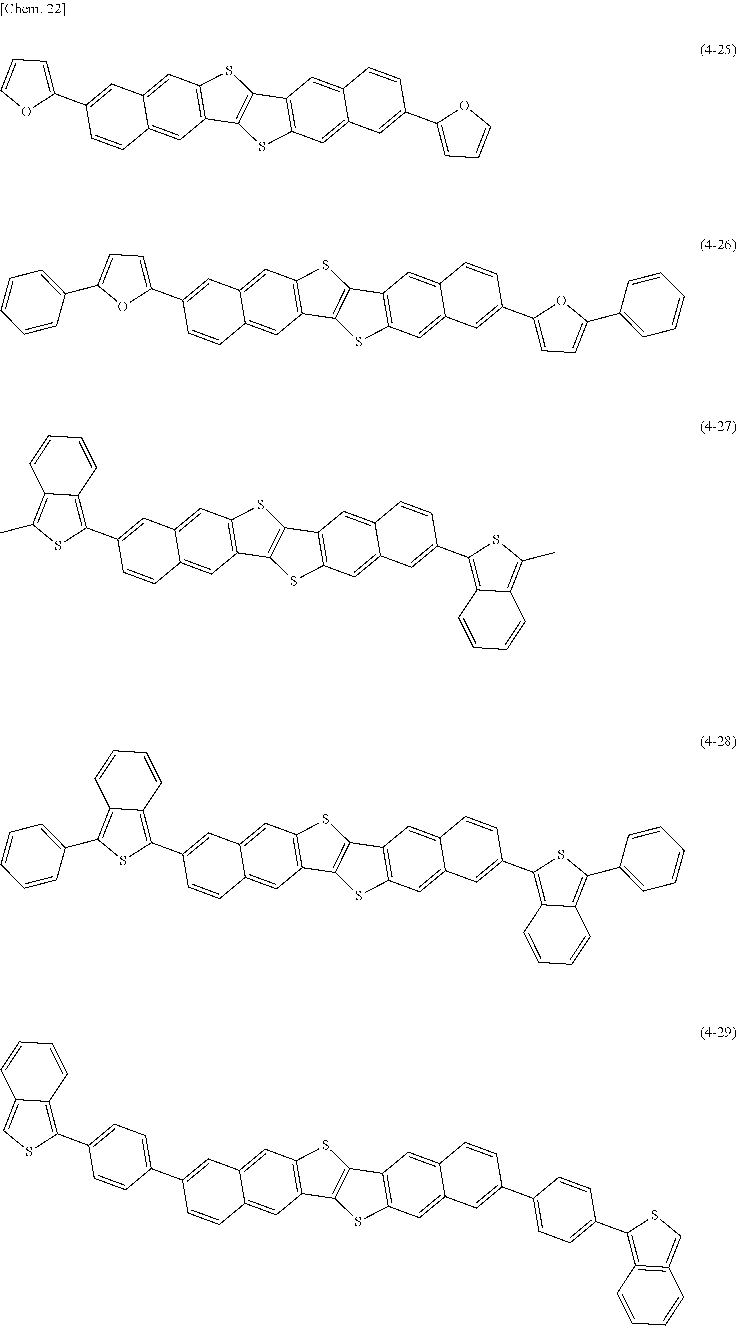

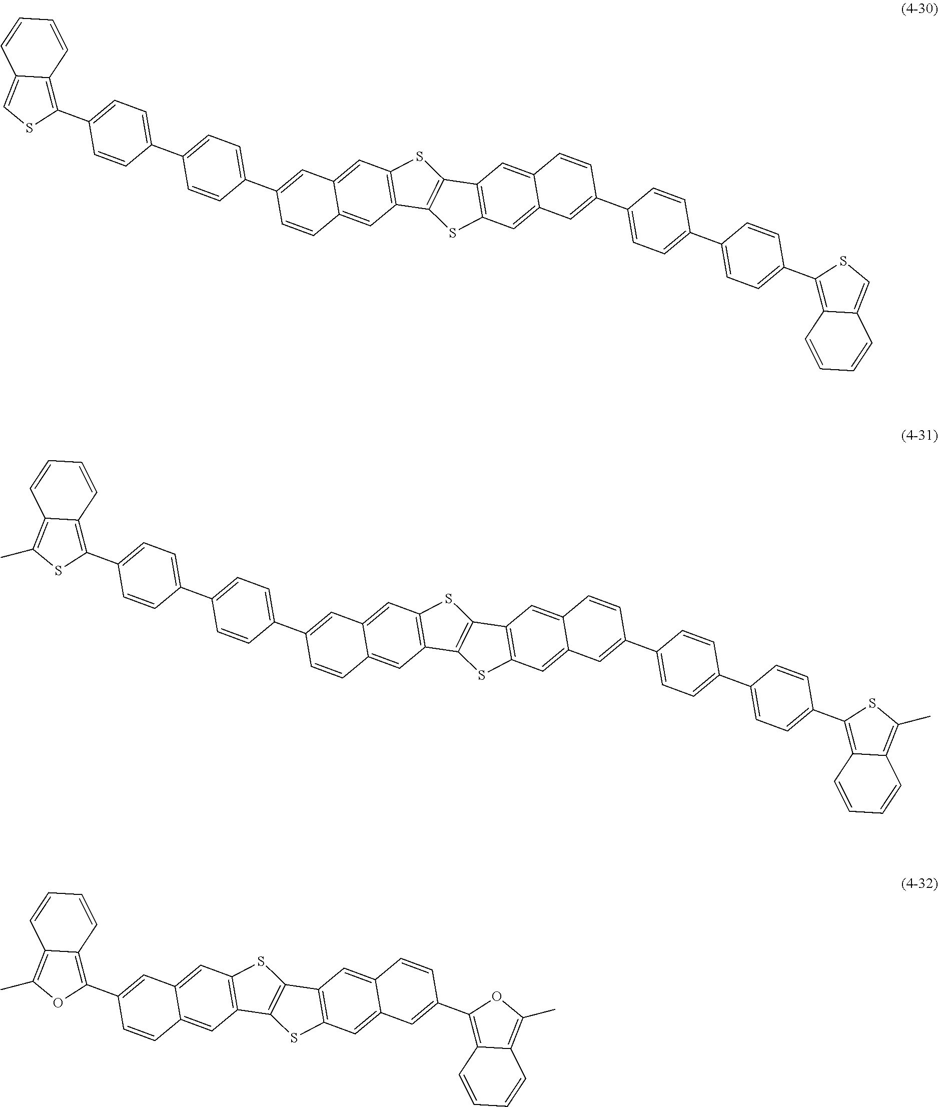

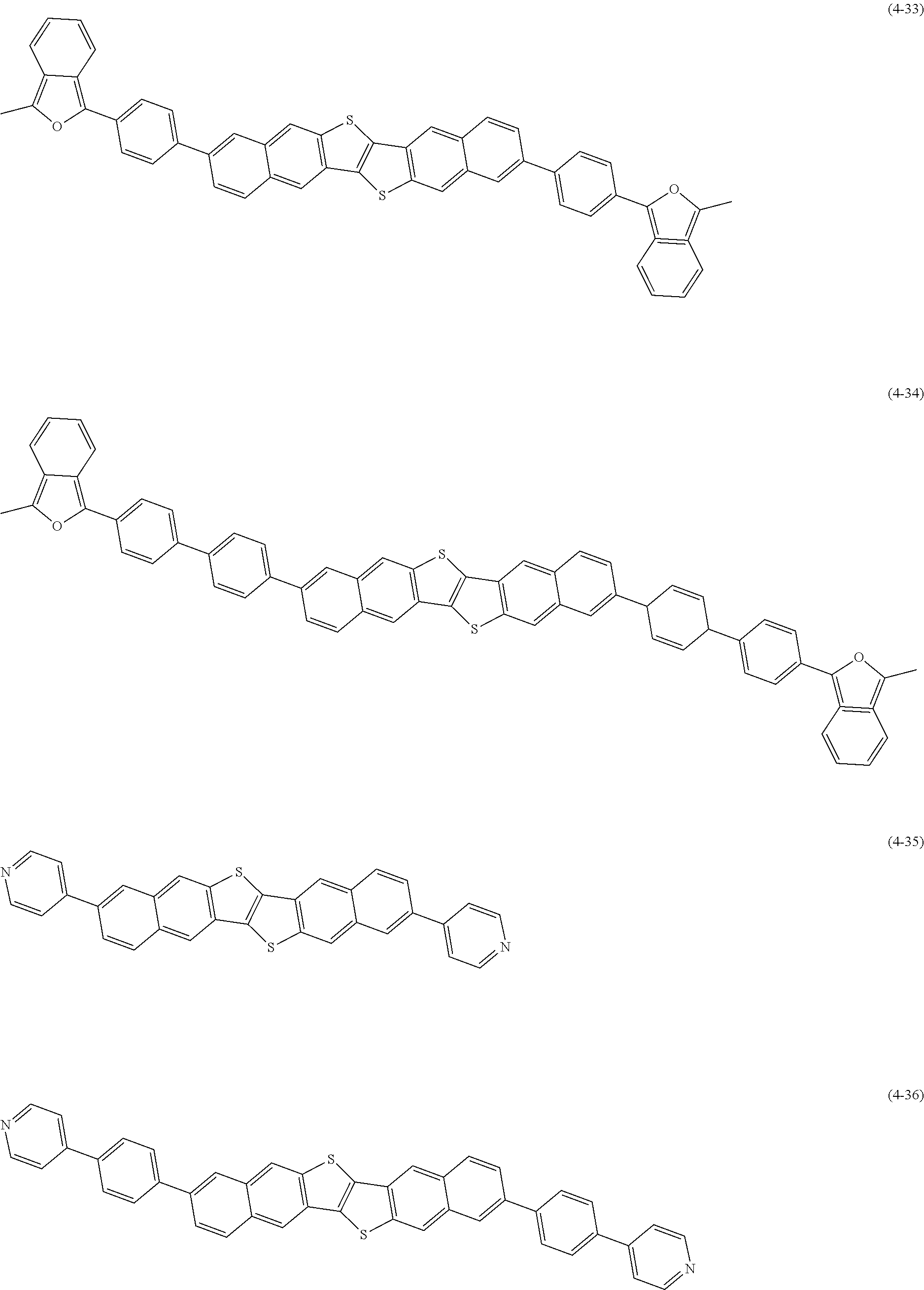

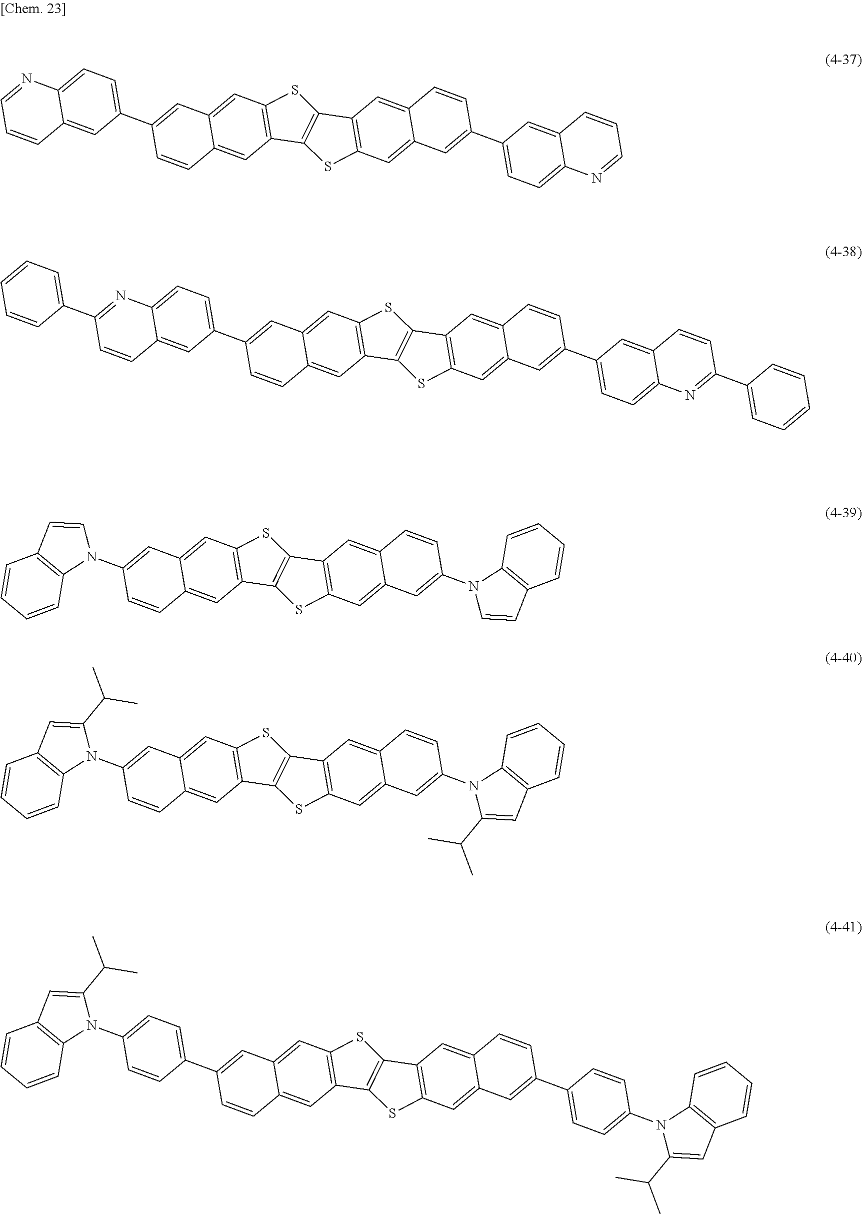 [SMILES: c1cnc2ccc(-c3ccc4cc5c(cc4c3)sc3c4cc6ccc(-c7ccc8ncccc8c7)cc6cc4sc53)cc2c1 ; c1ccc(-c2ccc3cc(-c4ccc5cc6c(cc5c4)sc4c5cc7ccc(-c8ccc9nc(-c%10ccccc%10)ccc9c8)cc7cc5sc64)ccc3n2)cc1 ; c1ccc2c(c1)ccn2-c1ccc2cc3c(cc2c1)sc1c2cc4ccc(-n5ccc6ccccc65)cc4cc2sc31 ; CC(C)c1cc2ccccc2n1-c1ccc2cc3c(cc2c1)sc1c2cc4ccc(-n5c(C(C)C)cc6ccccc65)cc4cc2sc31 ; CC(C)c1cc2ccccc2n1-c1ccc(-c2ccc3cc4c(cc3c2)sc2c3cc5ccc(-c6ccc(-n7c(C(C)C)cc8ccccc87)cc6)cc5cc3sc42)cc1]

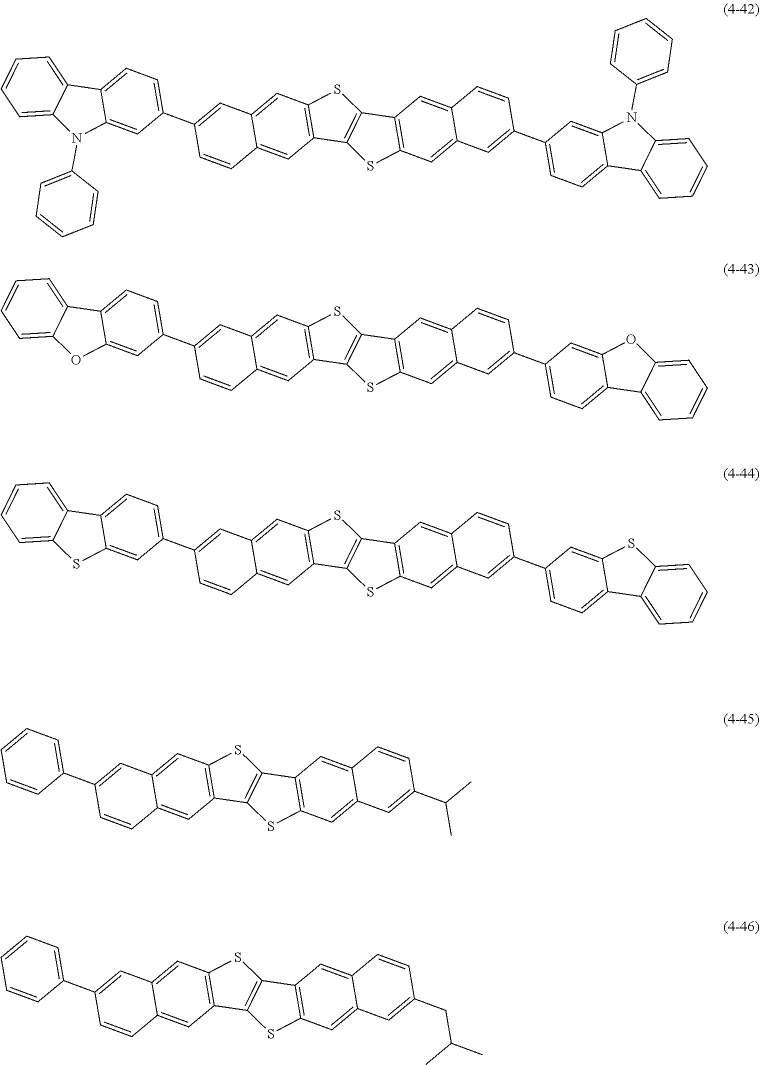

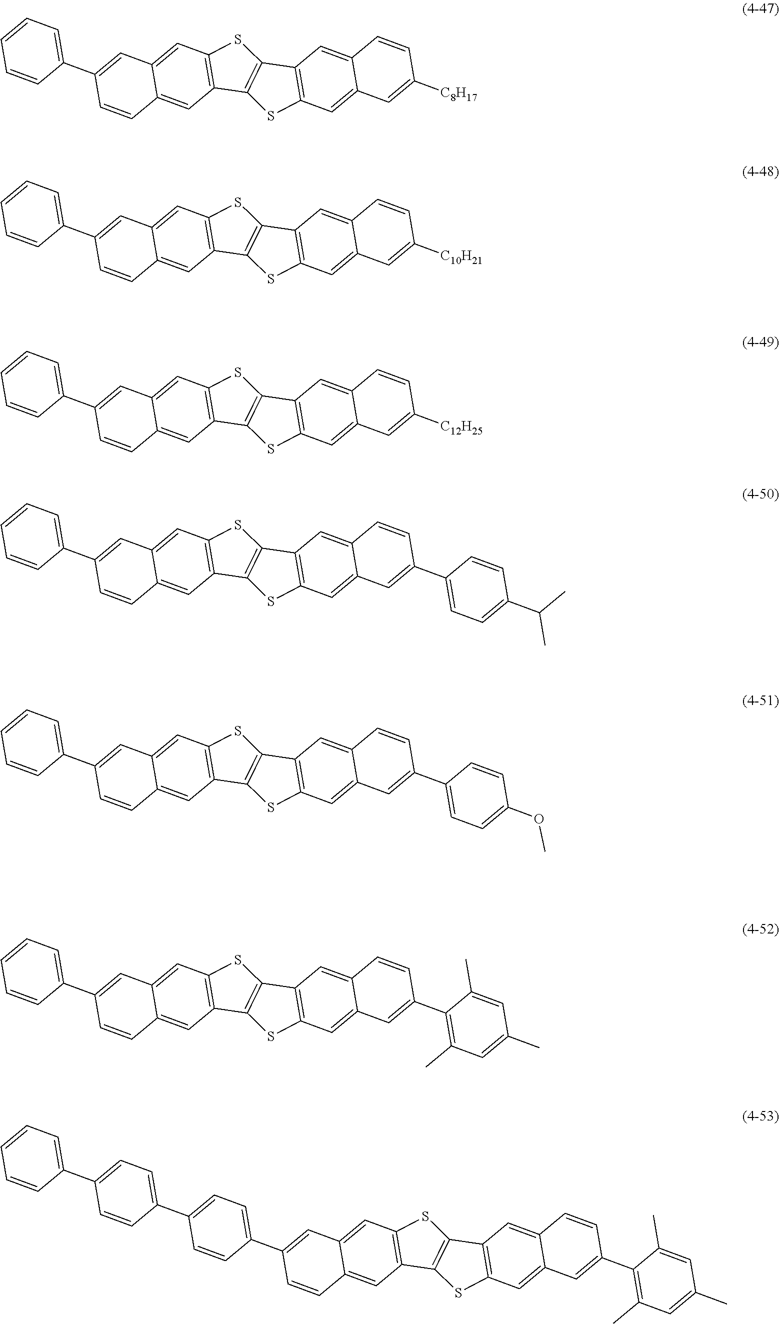

In addition, it is possible to use a p-type organic semiconductor (hereinafter, referred to as a p-type semiconductor) as the host material. Examples of the p-type semiconductor include thienoacene-based materials typified by a naphthalene derivative, an anthracene derivative, a phenanthrene derivative, a pyrene derivative, a perylene derivative, a tetracene derivative, a pentacene derivative, a quinacridone derivative, a thiophene derivative, a thienothiophene derivative, a benzothiophene derivative, a dianthracenothienothiophene (DATT) derivative, a benzobisbenzothiophene (BBBT) derivative, a thienobisbenzothiophene (TBBT) derivative, a dibenzothienobisbenzothiophene (DBTBT) derivative, a dithienobenzodithiophene (DTBDT) derivative, a dibenzothienodithiophene (DBTDT) derivative, a benzodithiophene (BDT) derivative, a naphthodithiophene (NDT) derivative, an anthracenodithiophene (ADT) derivative, a tetracenodithiophene (TDT) derivative, and a pentacenodithiophene (PDT) derivative. In addition, examples of the p-type semiconductor include a triarylamine derivative, a carbazole derivative, a picene derivative, a chrysene derivative, a fluoranthene derivative, a phthalocyanine derivative, a subphthalocyanine derivative, a subporphyrazine derivative, a metal complex including a heterocyclic compound as a ligand, a polythiophene derivative, a poly benzothiadiazole derivative, and a polyfluorene derivative.

In addition, it is possible to use an n-type organic semiconductor (hereinafter, referred to as an n-type semiconductor) as the host material. Examples of the n-type semiconductor include a fullerene and a derivative thereof. The fullerene is typified by an endohedral fullerene and a higher fullerene such as fullerene C₆₀, fullerene C₇₀, or fullerene C₇₄. Examples of a substituent included in the fullerene derivative include a halogen atom, a linear, branched, or cyclic alkyl group or phenyl group, a linear or fused group including an aromatic compound, a group including a halide, a partial fluoroalkyl group, a perfluoroalkyl group, a silyl alkyl group, a silyl alkoxy group, an aryl silyl group, an aryl sulfanyl group, an alkyl sulfanyl group, an aryl sulfonyl group, an alkyl sulfonyl group, an aryl sulfide group, an alkyl sulfide group, an amino group, an alkyl amino group, an aryl amino group, a hydroxy group, an alkoxy group, an acyl amino group, an acyloxy group, a carbonyl group, a carboxy group, a carboxamide group, a carboalkoxy group, an acyl group, a sulfonyl group, a cyano group, a nitro group, a group including a chalcogenide, a phosphine group, a phosphone group, and derivatives thereof. Specific examples of the fullerene derivative include fullerene fluoride, a PCBM fullerene compound, and a fullerene multimer. In addition, examples of the n-type semiconductor include an organic semiconductor having a HOMO level and a LUMO level that are larger (deeper) than those of the p-type semiconductor, and an inorganic metal oxide having light transmissivity.

Examples of the n-type semiconductor include a heterocyclic compound containing a nitrogen atom, an oxygen atom, or a sulfur atom. Specific examples thereof include an organic molecule including, as a portion of a molecular skeleton, a pyridine derivative, a pyrazine derivative, a pyrimidine derivative, a triazine derivative, a quinoline derivative, a quinoxaline derivative, an isoquinoline derivative, an acridine derivative, a phenazine derivative, a phenanthroline derivative, a tetrazole derivative, a pyrazole derivative, an imidazole derivative, a thiazole derivative, an oxazole derivative, an imidazole derivative, a benzimidazole derivative, a benzotriazole derivative, a benzoxazole derivative, a benzoxazole derivative, a carbazole derivative, a benzofuran derivative, a dibenzofuran derivative, a subporphyrazine derivative, a polyphenylene vinylene derivative, a polybenzothiadiazole derivative, a polyfluorene derivative, or the like, an organic metal complex, a subphthalocyanine derivative, a quinacridone derivative, a cyanine derivative, and a merocyanine derivative.

It is to be noted that the organic semiconductor is frequently classified into a p-type and an n-type. The p-type means that holes are easily transported, and the n-type means that electrons are easily transported. Accordingly, the p-type semiconductor and the n-type semiconductor described above are not limited to an interpretation that the p-type semiconductor and the n-type semiconductor include holes or electrons as majority carriers in thermal excitation, as in inorganic semiconductors.

The dopant material is a “light absorption material” of the present disclosure, and absorbs light, for example, in the visible light region to the near-infrared region of 400 nm or more and 900 nm or less. Specifically, for example, in a case where the light-emitting elements 10 (light-emitting elements 10R, 10G, and 10B) that emit corresponding pieces of color light in respective pixels (a red pixel R, a green pixel G, and a blue pixel B) are disposed in a display device 1 described later, it is preferable to use respective dopants each having an emission peak in a corresponding wavelength range. For example, in the light-emitting element 10 disposed in the red pixel R, it is preferable to use a dopant having an emission peak in a wavelength range of 590 nm or more and 750 m or less. In the light-emitting element 10 disposed in the green pixel G, it is preferable to use a dopant having an emission peak in a wavelength range of 500 nm or more and less than 590 nm. In the light-emitting element 10 disposed in the blue pixel B, it is preferable to use a dopant having an emission peak in a wavelength range of 410 nm or more and less than 500 nm. Further, for example, in an optical touchless sensor, a human-detecting sensor, a vital sensing device typified by oxygen saturation measurement, and an application of sensing biometric information typified by a vein imaging device, it is preferable to use a dopant having an emission peak in a wavelength range of 750 nm or more and less than 1300 nm.

Changing a molecular structure of the dopant material makes it possible to emit light of various wavelengths in the visible light region to the near-infrared region. Examples of the dopant material include a styrylbenzene derivative, an oxazole derivative, a perylene derivative, a coumarin derivative, an acridine derivative, an anthracene derivative, a naphthacene derivative, a pentacene derivative, a chrysene derivative, a pyrene derivative, a phthalocyanine derivative, a subphthalocyanine derivative, a naphthalocyanine derivative, a diketopyrrolopyrrole derivative, a pyrromethene skeleton compound, a metal complex, a quinacridone derivative, a cyanomethylenepyran-based derivative (DCM, DCJTB), a benzothiazole derivative, a benzimidazole derivative, and a metal chelated oxinoid compound. In addition, examples of the dopant material include a phosphorescent compound (a phosphorescent dopant). The phosphorescent compound is a compound that is able to emit light from a triplet exciton. The phosphorescent compound is not particularly limited as long as the phosphorescent compound emits light from a triplet exciton, but is preferably a metal complex including at least one kind of metal selected from the group consisting of Ir, Ru, Pd, Pt, Os, and Re. Specifically, a porphyrin metal complex or an ortho-metalated metal complex is more preferable. Examples of the porphyrin metal complex include a porphyrin platinum complex. The phosphorescent compound may be used alone, or two or more kinds of the phosphorescent compounds may be used in combination.

The light-emitting layer 14 has, for example, a thickness of 1×10⁻⁸ m or more and 2×10⁻⁷ m or less, preferably 1×10⁻⁸ m or more and 1×10⁻⁷ m or less, and more preferably 2.5×10⁻⁸ m or more and 1×10⁻⁷ m or less.

The electron transport layer 15 may be provided between the light-emitting layer 14 and the cathode 17. The electron transport layer 15 corresponds to a specific example of a “second buffer layer” of the present disclosure. A material having a work function larger (deeper) than that of the material usable for the hole transport layer 13 is preferable as a material included in the electron transport layer 15. Examples of such a material include an organic molecule and an organic metal complex including, as a portion of a molecular skeleton, a heterocycle including nitrogen (N), such as pyridine, quinoline, acridine, indole, imidazole, benzimidazole, phenanthroline, naphthalenetetracarboxylic acid diimide, naphthalenedicarboxylic acid monoimide, hexaazatriphenylene, or hexaazatrinaphthylene. Further, a material having small absorption in the visible light region is preferable. In addition, in a case where the electron transport layer 15 is formed by a thin film of about 5×10⁻⁹ m or more and about 2×10⁻⁸ m or less, it is possible to use a fullerene having absorption in the visible light region of 400 nm or more and 700 nm or less, and a derivative thereof. The fullerene is typified by fullerene C₆₀ and fullerene C₇₀.

The electron transport layer 15 has, for example, a thickness of 5×10⁻⁹ m or more and 5×10⁻⁷ m or less, preferably 5×10⁻⁹ m or more and 2×10⁻⁷ m or less, and more preferably 5×10⁻⁹ m or more and 1×10⁻⁷ m or less.

The electron injection layer 16 may be provided between the light-emitting layer 14 and the cathode 17. The electron injection layer 16 is adapted to improve electrical coupling between the electron transport layer 15 and the cathode 17. Examples of a material included in the electron injection layer 16 include an alkali metal such as lithium (Li), sodium (Na), or potassium (K), and a halide, an oxide, or a complex compound thereof. In addition, examples of the material included in the electron injection layer 16 include an alkaline earth metal such as magnesium (Mg) or calcium (Ca), and a halide, an oxide, or a complex compound thereof. Providing the electron injection layer 16 improves efficiency of injecting electrons into the light-emitting element 10.

The cathode 17 injects electrons into the light-emitting layer 14. In a case of configuring stacked light-emitting elements 20A and 20B described later, or, for example, in a case where light emission in the light-emitting layer 14 is extracted from the side of the cathode 17, the cathode 17 is configured by an electrically conductive film having light transmissivity. In this case, examples of a constituent material of the cathode 17 include an electrically conductive metal oxide, in a similar manner to the anode 11. Specific examples thereof include indium oxide (In₂O₃), and indium tin oxide (ITO) that is In₂O₃ doped with tin (Sn) as a dopant. As for crystallinity, the ITO thin film may have high crystallinity or low crystallinity (close to amorphous). Examples of the constituent material of the anode 11 include, in addition to the above, IFO that is In₂O₃ doped with fluorine (F) as a dopant. In addition, examples thereof include a tin oxide (SnO₂)-based material doped with a dopant, such as ATO doped with Sb as a dopant or FTO doped with F as a dopant. Further, zinc oxide (ZnO) or a zinc oxide-based material doped with a dopant may be used. Examples of the ZnO-based material include aluminum zinc oxide (AZO) doped with aluminum (Al) as a dopant, gallium-zinc oxide (GZO) doped with gallium (Ga), boron zinc oxide doped with boron (B), and indium-zinc oxide (IZO) doped with indium (In). Furthermore, indium-gallium oxide (IGO) doped with indium as a dopant or indium-gallium-zinc oxide (IGZO, In—GaZnO₄) doped with indium and gallium as dopants may be used. In addition, titanium oxide (TiOx), antimony oxide (SbOₓ), tungsten oxide (WOₓ), molybdenum oxide (MoOₓ), a spinel oxide, or an oxide having a YbFe2O4 structure may be used as the constituent material of the anode 11. In addition, examples of the constituent material of the anode 11 may include an electrically conductive material including, as a main component, gallium oxide, titanium oxide, niobium oxide, nickel oxide, or the like.

The cathode 17 has, for example, a thickness of 2×10⁻⁸ m or more and 2×10⁻⁷ m or less, preferably 3×10⁻⁸ m or more and 1.5×10⁻⁷ m or less.

In a case where there is no necessity that the cathode 17 has light transmissivity (e.g., in a case where light is extracted from the side of the anode 11), it is possible to use a single metal or an alloy having a low work function (e.g., φ=3.5 eV to 4.5 eV). Specific examples thereof include alkali metals (e.g., Li, Na, and K), fluorides or oxides thereof, alkaline earth metals (e.g., Mg and Ca), and fluorides or oxides thereof. In addition, examples thereof include Al, Zn, Sn, Tl, a sodium-potassium alloy, an aluminum-lithium alloy, a magnesium-silver alloy, a rare earth metal such as indium or ytterbium, and alloys thereof.

Further, examples of the material included in the cathode 17 include electrically conductive substances, including a metal such as Pt, Au, Pd, Cr, Ni, Al, Ag, Ta, W, Cu, Ti, In, Sn, Fe, Co, or Mo, alloys including these metal elements, electrically conductive particles including these metals, electrically conductive particles of alloys including these metals, polysilicon containing an impurity, a carbon-based material, an oxide semiconductor, a carbon nanotube, and graphene. In addition, the cathode 17 may include a stacked film of layers including the above-described metal elements.

Furthermore, examples of the material included in the cathode 17 include an organic material (an electrically conductive macromolecule) such as poly(3,4-ethylenedioxythiophene)/polystyrene sulfonate [PEDOT/PSS]. Alternatively, the above-described electrically conductive materials may be mixed with a binder (a macromolecule) into a paste or an ink, and the paste or the ink may be cured and used as the cathode 17.

Further, examples of the material included in the cathode 17 include electrically conductive substances, including a metal such as Pt, Au, Pd, Cr, Ni, Al, Ag, Ta, W, Cu, Ti, In, Sn, Fe, Co, or Mo, alloys including these metal elements, electrically conductive particles including these metals, electrically conductive particles of alloys including these metals, polysilicon containing an impurity, a carbon-based material, an oxide semiconductor, a carbon nanotube, and graphene.

Moreover, metal nanoparticles may be caused to adhere onto the cathode 17. Preferably, Au, Ag, or Cu is selected as the metal nanoparticles. Causing such metal nanoparticles to adhere onto the cathode 17 makes it possible to achieve the plasmon resonance effect to improve the light emission efficiency of the light-emitting element 10.

It is possible to form the organic layers (the hole injection layer 12, the hole transport layer 13, the light-emitting layer 14, the electron transport layer 15, and the electron injection layer 16) included in the above-described light-emitting element 10 using, for example, a dry film formation method and a wet film formation method. Examples of the dry film formation method include a vacuum deposition method using resistance heating or high frequency heating, and an ion beam (EB) deposition method. In addition, examples of the dry film formation method include various sputtering methods such as a magnetron sputtering method, an RF-DC coupled bias sputtering method, an ECR sputtering method, a facing-target sputtering method, or a high frequency sputtering method, an ion plating method, a laser ablation method, a molecular beam epitaxy method, and a laser transfer method. Furthermore, examples of the dry film formation method include a CVD method such as a plasma CVD method, a thermal CVD method, an MOCVD method, or an optical CVD method. Examples of the wet film formation method include a spin coating method, an ink jet method, a spray coating method, a stamping method, a microcontact printing method, a flexographic printing method, an offset printing method, a gravure printing method, and a dipping method. As patterning, it is possible to use chemical etching such as a shadow mask, laser transfer, or photolithography, physical etching by ultraviolet rays or laser, and the like. As a planarization technique, it is possible to use a laser planarization method, a reflow method, and the like.

It is possible to use, for example, the dry film formation method or the wet film formation method for the electrodes (the anode 11 and the cathode 17) included in the above-described light-emitting element 10. Examples of the dry film formation method include a PVD method and a CVD method. Examples of a film formation method using the principle of the PVD method include a vacuum deposition method, an EB deposition method, various sputtering methods described above, an ion plating method, a laser ablation method, a molecular beam epitaxy method, and a laser transfer method. In addition, examples thereof include various CVD methods described above. Examples of the wet film formation method include an electroplating method and an electroless plating method, in addition to the above-described methods. For the patterning and the planarization technique, it is possible to use, for example, a CMP method, in addition to the above-described methods.

It is to be noted that, in addition to the hole injection layer 12, the hole transport layer 13, the electron transport layer 15, and the electron injection layer 16, any other layer may be provided between the anode 11 and the light-emitting layer 14 and between the light-emitting layer 14 and the cathode 17. For example, a second hole transport layer and a second electron transport layer may be provided respectively between the anode 11 and the hole transport layer 13 and between the cathode 17 and the electron transport layer 15. Further, layers in contact with the anode 11 and the cathode 17 may contain metal nanoparticles of Au, Ag, Cu, or the like. This makes it possible to achieve the plasmon resonance effect to improve the light emission efficiency of the light-emitting element 10. Here, the layer in contact with the anode 11 corresponds to the hole injection layer 12 and the hole transport layer 13 in a case where the hole injection layer 12 is omitted. The layer in contact with the cathode 17 corresponds to the electron injection layer 16 and the electron transport layer 15 in a case where the electron injection layer 16 is omitted.

The light-emitting element 10 is formed on, for example, a substrate. Examples of a constituent material of the substrate include an organic polymer such as polymethyl methacrylate (polymethacrylic acid methyl: PMMA), polyvinyl alcohol (PVA), polyvinyl phenol (PVP), polyether sulfone (PES), a polyimide, polycarbonate (PC), polyethylene terephthalate (PET), or polyethylene naphthalate (PEN). The organic polymer has a form of a macromolecular material such as a plastic film, a plastic sheet, or a plastic substrate including a macromolecular material and having flexibility. Use of the substrate including a macromolecular material and having flexibility makes it possible to incorporate or integrate the light-emitting element 10 into, for example, an electronic apparatus having a curved surface shape.

In addition, examples of the substrate include various glass substrates, various glass substrates each including an insulating film formed on a surface thereof, a quartz substrate, a quartz substrate including an insulating film formed on a surface thereof, a silicon semiconductor substrate, and metal substrates including various metals or various alloys such as stainless steel and each including an insulating film formed on a surface thereof. It is to be noted that examples of the insulating film include silicon oxide-based materials (e.g., SiOₓ and spin-on glass (SOG)), silicon nitride (SiN_{y}), silicon oxynitride (SiON), aluminum oxide (Al2O3), a metal oxide, and a metal salt. Examples of the silicon oxide-based materials include silicon oxide (SiOₓ), BPSG, PSG, BSG, AsSG, PbSG, SiON, SOG (spin-on glass), and low dielectric constant materials (e.g., a polyarylether, a cycloperfluorocarbon polymer, benzocyclobutene, a cyclic fluororesin, polytetrafluoroethylene, a fluorinated aryl ether, a fluorinated polyimide, amorphous carbon, and organic SOG). In addition, it is possible to use an insulating film including an organic material. Examples of the insulating film including an organic material include a polyphenol-based material, a polyvinylphenol-based material, a polyimide-based material, a polyamide-based material, a polyamide-imide-based material, a fluorine-based polymer material, a borazine-silicon polymer material, and a truxene-based material, which are subjectable to lithography. It is possible to form the insulating film using, for example, a dry film formation method or a wet film formation method.

As the substrate, it is also possible to use an electrically conductive substrate (a substrate including a metal such as gold or aluminum, and a substrate including highly oriented graphite) including the above-described insulating film on a surface thereof. The surface of the substrate is desirably smooth, but may have roughness to the extent that the roughness does not influence the property of the light-emitting layer 14. Further, it is possible to improve adhesion between the substrate and the anode 11 or the cathode 17 by forming a silanol derivative on the surface of the substrate by a silane coupling method, forming a thin film including a thiol derivative, a carboxylic acid derivative, a phosphate derivative, or the like by a SAM method or the like, or forming an insulating thin film including a metal salt or a metal complex by a CVD method or the like. Further, a layer in contact with the substrate may contain metal nanoparticles of Au, Ag, Cu, or the like. This makes it possible to achieve the plasmon resonance effect to improve the light emission efficiency of the light-emitting element 10.

In some cases, the anode 11 and the cathode 17 may be each coated with a coating layer. Examples of a material included in the coating layer include a silicon oxide-based material, and an inorganic insulating material such as a metal oxide including SiN_{y}, Al2O3, or the like. In addition, examples of the material included in the coating layer include organic insulating materials (organic polymers), including PMMA, PVP, PVA, PC, PET, polystyrene, a silanol derivative (a silane coupling agent), and linear hydrocarbons such as octadecanethiol or dodecyl isocyanate having, at one end thereof, a functional group bondable to the electrode. Examples of the silanol derivative (the silane coupling agent) include N-2 (aminoethyl) 3-aminopropyltrimethoxysilane (AEAPTMS), 3-mercaptopropyltrimethoxysilane (MPTMS), and octadecyltrichlorosilane (OTS). The inorganic insulating material and the organic insulating material may be each used in combination.

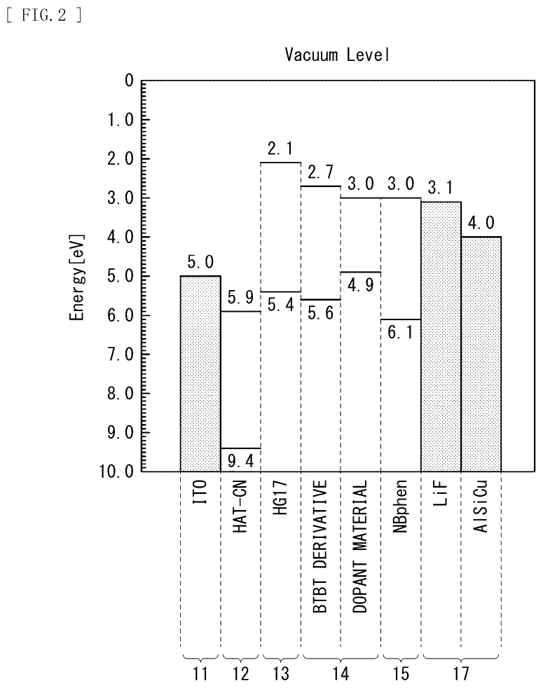

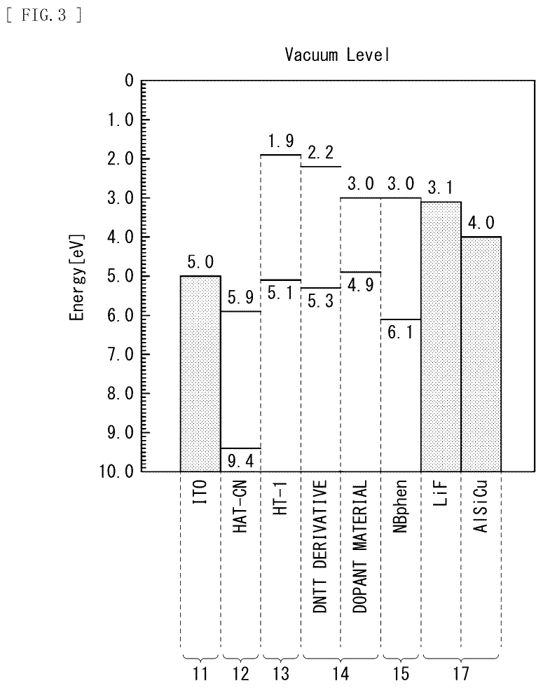

FIG. 2 illustrates an example of energy levels of materials included in respective layers (the anode 11, the hole injection layer 12, the hole transport layer 13, the light-emitting layer 14, the electron transport layer 15, and the cathode 17) of the light-emitting element 10 using the BTBT derivative as the host material. FIG. 3 illustrates another example of the energy levels of the materials included in the respective layers (the anode 11, the hole injection layer 12, the hole transport layer 13, the light-emitting layer 14, the electron transport layer 15, and the cathode 17) of the light-emitting element 10 using the DNTT derivative as the host material.

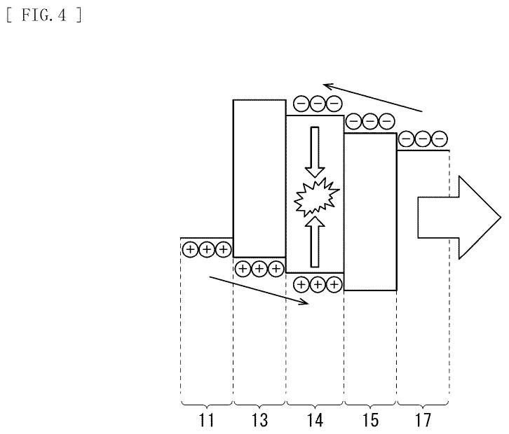

In the light-emitting element 10, applying a voltage to the anode 11 and the cathode 17 allows holes and electrons to be injected into the light-emitting layer 14 respectively from the anode 11 and the cathode 17, and light is emitted upon recombination of the holes and the electrons in the light-emitting layer 14, as illustrated in FIG. 4, for example. Providing the hole transport layer 13 and the electron transport layer 15 respectively between the light-emitting layer 14 and the anode 11 and between the light-emitting layer 14 and the cathode 17 makes it possible to adjust electrical coupling between the light-emitting layer 14 and each of the anode 11 and the cathode 17 and carrier balance of holes and electrons into the light-emitting layer 14.

In addition, as illustrated in FIGS. 2 and 3, electrons are blocked by making a LUMO level of the hole transport layer 13 shallow, and holes are blocked by making a HOMO level of the electron transport layer 15 deep, thereby confining carriers, i.e., holes and electrons, in the light-emitting layer 14. This makes it possible to improve a recombination rate. Moreover, excitons after the recombination are also confined, making it possible to improve the light emission efficiency.

Further, providing the hole injection layer 12 and the electron injection layer 16 respectively between the light-emitting layer 14 and the anode 11 and between the light-emitting layer 14 and the cathode 17 makes it possible to facilitate injection of holes from the anode 11 into the hole transport layer 13 and injection of electrons from the cathode 17 into the electron transport layer 15. Furthermore, providing the second hole transport layer and the second electron transport layer respectively between the anode 11 and the hole transport layer 13 and between the cathode 17 and the electron transport layer 15 as described above makes it possible to more smoothly transport holes and electrons from the hole transport layer 13 and the electron transport layer 15 to the light-emitting layer 14.

### (1-2. Configuration of Display Device)

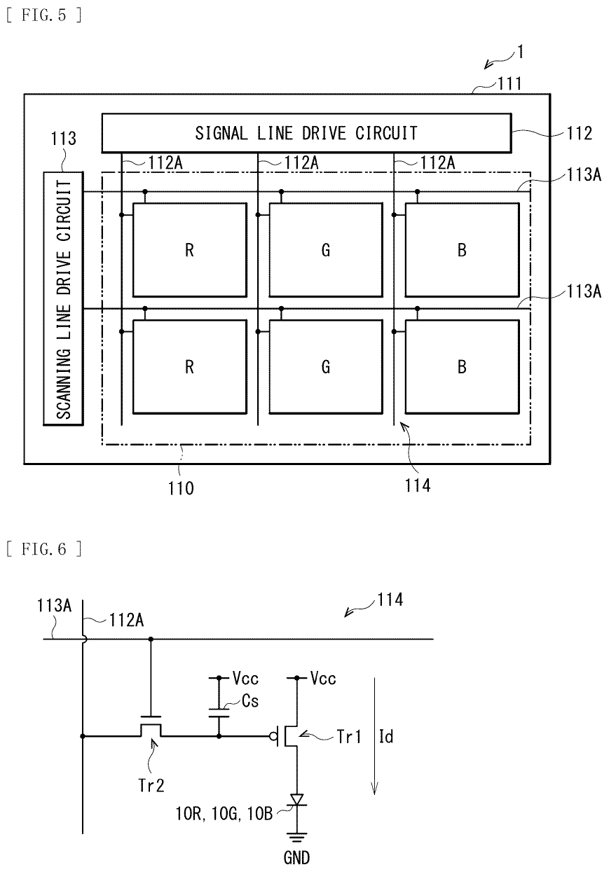

FIG. 5 schematically illustrates an example of a planar configuration of the display device 1 using the above-described light-emitting element 10. The display device 1 is, for example, an organic EL television, and is a top light emission system (top emission system) display device that extracts emitted light generated in the light-emitting layer 14 from a side opposite to a drive substrate 111.

The display device 1 includes, for example, on the drive substrate 111, a display region 110, and a signal line drive circuit 112 and a scanning line drive circuit 113 that are drivers adapted for picture display. The signal line drive circuit 112 and the scanning line drive circuit 113 are provided around the display region 110. In the display region 110, the plurality of light-emitting elements 10 (10R, 10G, and 10B) corresponding to respective pixels (the red pixel R, the green pixel G, and the blue pixel B) is disposed in a matrix, and a pixel drive circuit 114 is further formed.

FIG. 6 illustrates an example of the pixel drive circuit 114. The pixel drive circuit 114 is an active drive circuit formed in a lower layer of the anode 11. That is, the pixel drive circuit 114 is an active drive circuit including a driving transistor Tr1, a writing transistor Tr2, a capacitor (a storage capacitor) Cs between the transistors Tr1 and Tr2, and the light-emitting element 10R (10G or 10B). The light-emitting element 10R (10G or 10B) is coupled in series to the driving transistor Tr1 between a first power supply line (Vcc) and a second power supply line (GND). The driving transistor Tr1 and the writing transistor Tr2 each include a typical thin film transistor (TFT). For example, a configuration thereof may have an inverted staggered structure (a so-called bottom gate type) or may have a staggered structure (a top gate type).

In the pixel drive circuit 114, a plurality of signal lines 112A is disposed in a column direction, and a plurality of scanning lines 113A is disposed in a row direction. An intersection between each of the signal lines 112A and a corresponding one of the scanning lines 113A corresponds to one of the respective light-emitting elements 10, 10G, and 10B. Each of the signal lines 112A is coupled to the signal line drive circuit 112. An image signal is supplied from the signal line drive circuit 112 via the signal line 112A to a source electrode of the writing transistor Tr2. Each of the scanning lines 113A is coupled to the scanning line drive circuit 113. Scanning signals are sequentially supplied from the scanning line drive circuit 113 via the scanning line 113A to a gate electrode of the writing transistor Tr2.

In the display device 1, the scanning signal is supplied from the scanning line drive circuit 113 to each of the pixels via the gate electrode of the writing transistor Tr2, and the image signal is held in the storage capacitor Cs from the signal line drive circuit 112 via the writing transistor Tr2. That is, on/off of the driving transistor Tr1 is controlled depending on a signal held in the storage capacitor Cs, thereby allowing a drive current Id to be injected into the light-emitting element 10 to lead to light emission upon recombination of holes and electrons. The light is extracted by being transmitted through the anode 11 and the drive substrate 111 in a case of bottom light emission (bottom emission), and by being transmitted through the cathode 17 and an opposed substrate in a case of top light emission (top emission).

It is to be noted that a microlens or a light-blocking layer may be provided on a side of a light extraction surface of the light-emitting element 10 as necessary. Further, an optical cut filter adapted to adjust an emission spectrum may be provided.

It is possible to provide the microlens on a top of or inside the light-emitting element 10. Changing a shape or a constituent material of the microlens makes it possible to freely control a direction of radiation from the light-emitting element 10. For example, the microlens enables front luminance or front radiant flux to improve by condensing radiated light, and conversely, also enables light to be radiated to allow for isotropically equivalent luminance or radiant flux. This makes it possible to improve the front luminance of the display device 1 and adjust a viewing angle. Examples of the constituent material of the microlens include a resin such as a siloxane-based resin, a methacrylate-based resin, or an epoxy-based resin, an inorganic material such as glass or quartz, and an organic-inorganic hybrid material.

As the light-blocking layer, a partition wall having a shape of a screen, called a rib, may be formed between the contiguous light-emitting elements 10, or a thin film having a light-blocking effect may be formed between the contiguous light-emitting elements 10, for example, as in a black matrix usable for a liquid crystal display.

### (1-3. Workings and Effects)

In the light-emitting element 10 according to the present embodiment, the light-emitting layer 14 includes at least one kind of a heteroacene derivative having, in a molecule, one skeleton represented by the general formula (1) or the general formula (2) described above. Description is given below of this point.

In recent years, research and development have been progressing of electronic devices using organic semiconductors in place of inorganic semiconductors. An example of the organic semiconductors is organic semiconductors each including a combination of fluorene and carbazole, as described above. These organic semiconductors are used for a hole injection layer or a hole transport layer of an organic electroluminescent element, and are known as materials having excellent hole transportability.

Incidentally, in a case where electronics devices are fabricated using these materials, further improvement is desired depending on usage. For example, electronic devices for biometric authentication and for vital sensing are desired to be more compact, easy to constantly wear, and affordable at a low cost. As sensors included in these electronic devices, light-receiving/emitting elements for the near-infrared region in addition to the visible light region play an important role. Therefore, if it is possible to fabricate the elements by a simple method such as vapor deposition film formation or application film formation, it is possible to increase options of substrates and reduce a manufacturing cost.

However, the light-emitting elements that are able to be fabricated by a simple method such as vapor deposition film formation or application film formation have an issue that the light emission efficiency particularly in the near-infrared region is low. An example of such light-emitting elements is an organic EL element. For the organic EL element, development has been progressing of materials and element structures that obtain light emission in the visible light region, whereas development has not made much progress of materials for usage in the near-infrared region. For example, it is desired to develop light-emitting materials and element structures that exhibit high light emission efficiency in a wavelength region of 750 nm or more. Such a wavelength region is effective for sensing biometric information.

Meanwhile, in the present embodiment, the light-emitting layer 14 includes at least one kind of a heteroacene derivative having, in a molecule, one skeleton represented by the general formula (1) or the general formula (2) described above. This allows for improved carrier transportability and efficient transfer of energy to the dopant material in the light-emitting layer 14.

As described above, it is possible for the light-emitting element 10 according to the present embodiment to have an improved electrical property such as a reduced drive voltage, an improved light emission external quantum yield, or improved light emission electric power efficiency.

Next, description is given of a modification example, application examples, and examples of the present disclosure. Hereinafter, components similar to those of the above-described embodiment are denoted by the same reference numerals, and description thereof is omitted as appropriate.

### 2. MODIFICATION EXAMPLE

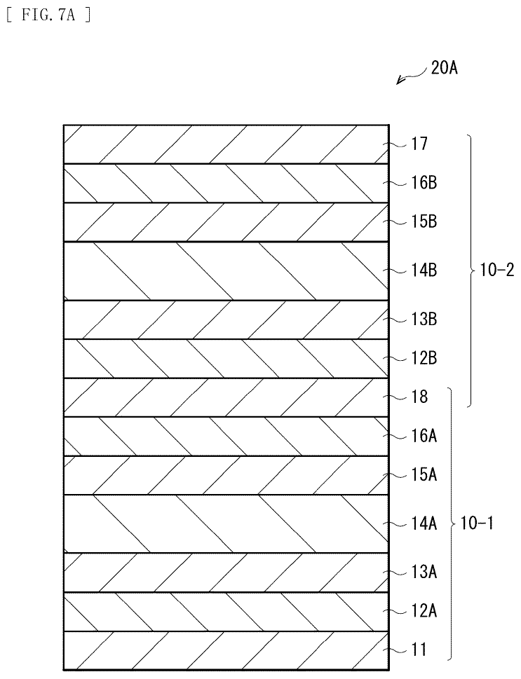

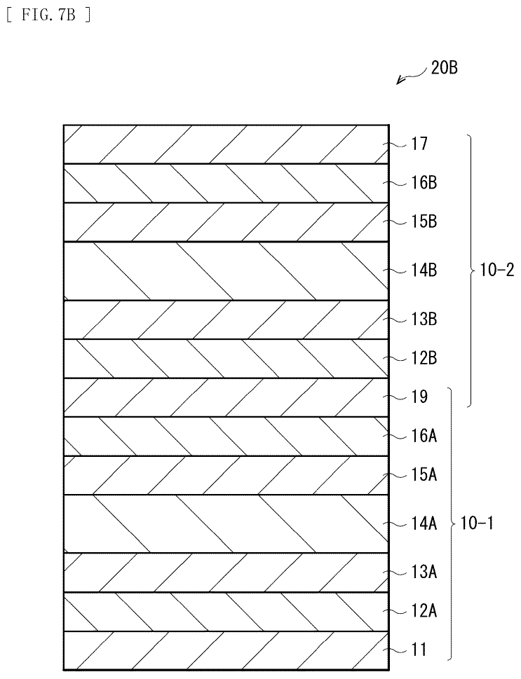

FIG. 7A schematically illustrates an example of a cross-sectional configuration of a light-emitting element (a light-emitting element 20A) according to a modification example of the present disclosure. FIG. 7B schematically illustrates another example of the cross-sectional configuration of the light-emitting element (a light-emitting element 20B) according to the modification example of the present disclosure. The light-emitting elements 20A and 20B are each, for example, a so-called organic electroluminescent element (an organic EL element) usable as a light source in an organic EL television and the like, in a similar manner to the above-described embodiment.

The light-emitting elements 20A and 20B according to the present modification example each have a configuration in which two light-emitting elements 10 (10-1 and 10-2) according to the above-described embodiment are stacked on each other. One electrode of the electrodes between the two light-emitting elements, i.e., the light-emitting element 10-1 and the light-emitting element 10-2, may be omitted and another electrode of the electrodes may be configured as an intermediate electrode 18, as in, for example, the light-emitting element 20A illustrated in FIG. 7A. Alternatively, the electrodes may be replaced with a charge generation layer 19, as in the light-emitting element 20B illustrated in FIG. 7B.

Examples of a material included in the charge generation layer 19 include an aromatic amine-based material, a carbazole derivative, an indolocarbazole derivative, a naphthalene derivative, an anthracene derivative, a phenanthrene derivative, a pyrene derivative, a perylene derivative, a tetracene derivative, a pentacene derivative, a perylene derivative, a picene derivative, a chrysene derivative, a fluoranthene derivative, a phthalocyanine derivative, a subphthalocyanine derivative, a hexaazatriphenylene derivative, a hexaazatrinaphthylene derivative, a naphthalenetetracarboxylic acid diimide derivative, a naphthalenedicarboxylic acid monoamide derivative, a metal complex including a heterocyclic compound as a ligand, a thiophene derivative, a thienoacene-based material, a heteroacene-based material, poly(3,4-ethylenedioxythiophene)/polystyrene sulfonate [PEDOT/PSS], and polyaniline. Examples of the aromatic amine-based material include a triarylamine compound, a benzidine compound, and a styrylamine compound. Examples of the thienoacene-based material include a thienothiophene (TT) derivative, a benzothiophene (BT) derivative, a benzothienobenzothiophene (BTBT) derivative, a dinaphthothienothiophene (DNTT) derivative, a dianthracenothienothiophene (DATT) derivative, a benzobisbenzothiophene (BBBT) derivative, a thienobisbenzothiophene (TBBT) derivative, a dibenzothienobisbenzothiophene (DBTBT) derivative, a dithienobenzodithiophene (DTBDT) derivative, a dibenzothienodithiophene (DBTDT) derivative, a benzodithiophene (BDT) derivative, a naphthodithiophene (NDT) derivative, an anthracenodithiophene (ADT) derivative, a tetracenodithiophene (TDT) derivative, and a pentacenodithiophene (PDT) derivative. In addition, examples of the material included in the charge generation layer 19 include a metal oxide such as MoOx, RuOx, VOx, or WOx.

### 3. APPLICATION EXAMPLES

### (Module)

The display device 1 according to the above-described embodiment is applicable, for example, as a module 100 as illustrated in FIG. 8, to an electronic apparatus that displays, as an image or a picture, a picture signal inputted from the outside or a picture signal internally generated. Examples of such an electronic apparatus include a television, a digital still camera, a notebook personal computer, a mobile terminal such as a mobile telephone, and a video camera.

The module 100 is provided with, for example, a region 210 exposed from a sealing substrate on one side of the drive substrate 111, and an external coupling terminal (not illustrated) is formed in the exposed region 210 by extending wiring of the signal line drive circuit 112 and the scanning line drive circuit 113. A flexible printed circuit substrate (FPC) 220 adapted for signal input/output may be provided at the external coupling terminal.

### Application Example 1

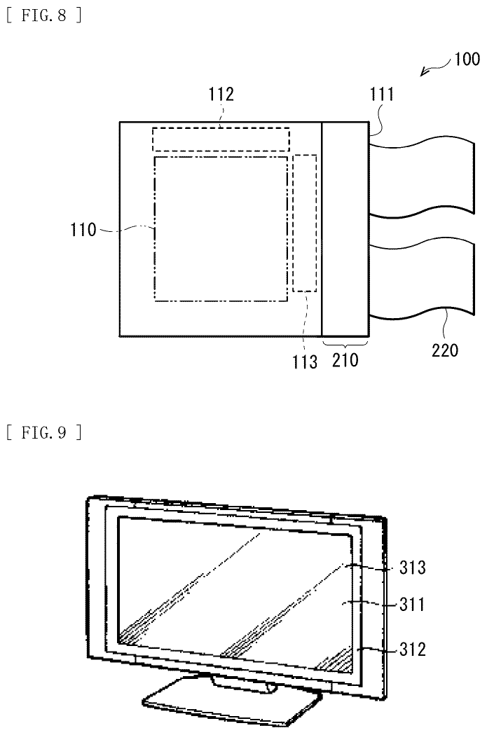

FIG. 9 illustrates an appearance configuration of a television. The television includes, for example, a picture display screen 311 (the display device 1) including a front panel 312 and filter glass 313.

### Application Example 2

FIGS. 10A and 10B illustrate an appearance of a smartphone according to Application Example 2. The smartphone includes, for example, a display unit 321 and an operator 322 on a front side, and includes a camera 323 on a back side. The display device 1 according to a second embodiment described above is mounted in a display unit 310.

### Application Example 3

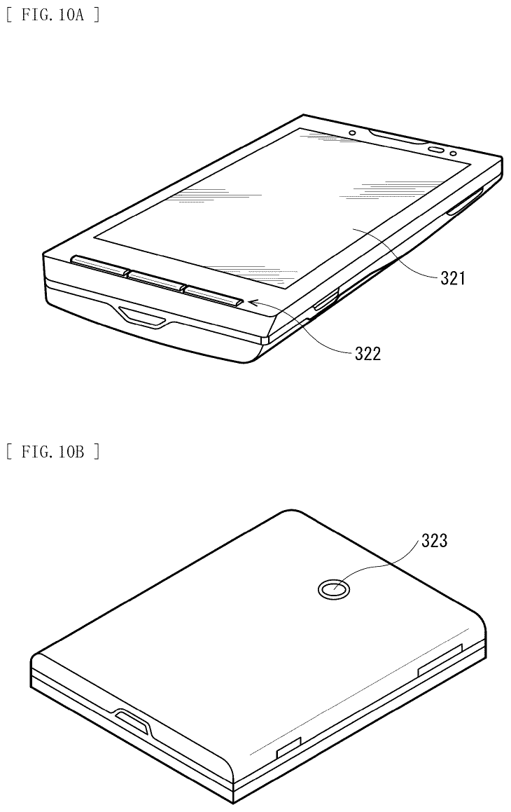

FIGS. 11A and 11B illustrate an appearance configuration of a tablet. The tablet includes, for example, a display unit 331 (the display device 1), a non-display unit (a housing) 332, and an operator 333. The operator 333 may be provided on a front surface of the non-display unit 332 as illustrated in FIG. 11A, or may be provided on an upper surface thereof as illustrated in FIG. 11B.

### Application Example 4

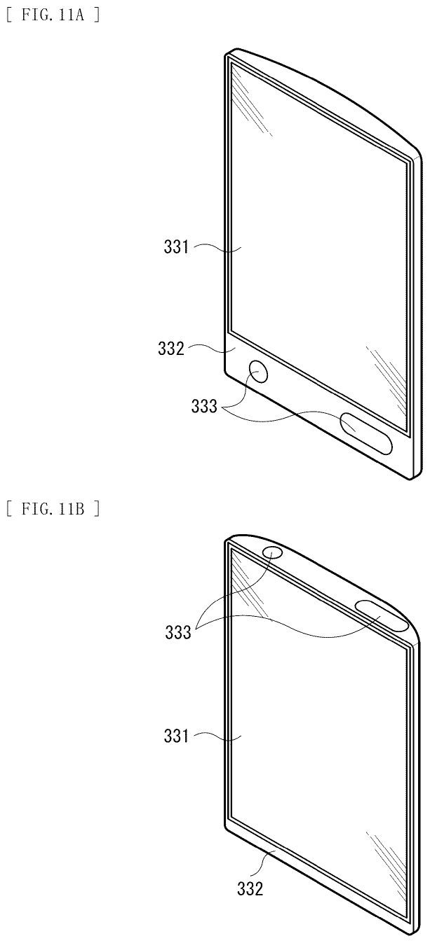

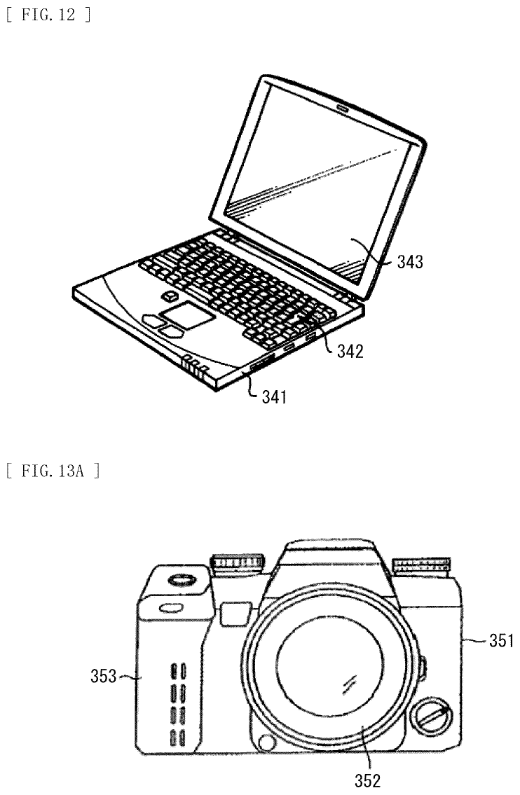

FIG. 12 illustrates an appearance configuration of a notebook personal computer. The personal computer includes, for example, a body 341, a keyboard 342 adapted for an operation of inputting characters and the like, and a display unit 343 (the display device 1) that displays an image.

### Application Example 5

FIGS. 13A and 13B illustrate an appearance configuration of a digital camera. The digital camera includes a body unit (a camera body) 351, an interchangeable lens unit 352, a grip unit 353 gripped by a user at the time of capturing an image, a monitor 354 (the display device 1) that displays various kinds of information, and an EVF (Electronic View Finder) 355 that displays a through image observed by a user at the time of capturing an image.

### Application Example 6

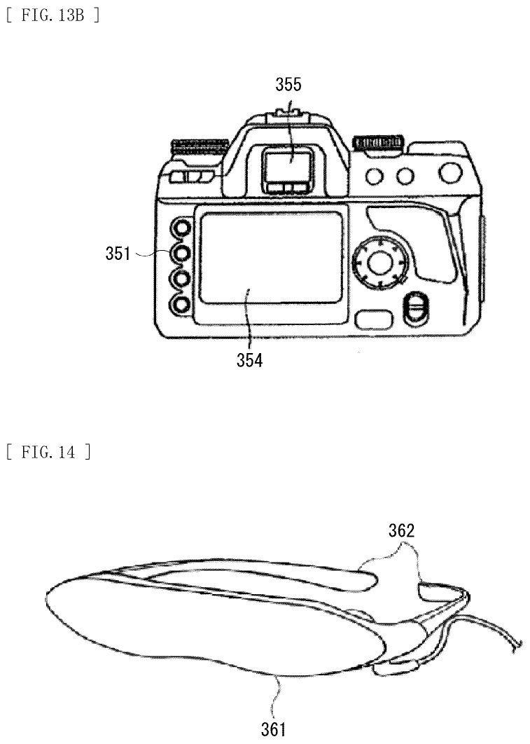

FIG. 14 illustrates an appearance configuration of a head-mounted display. The head-mounted display includes a spectacle-type display unit 361 (the display device 1) that displays various kinds of information, and an ear hook 362 hooked to ears of a user at the time of being worn.

In addition, the light-emitting element 10 and the like described above may be combined with a light-receiving element and the like. For example, a combination of the light-emitting element 10 that emits visible light and a light-receiving element that receives visible light is also applicable to a sheet scanner, a biometric authentication device typified by fingerprint imaging, a vital sensing device typified by pulse wave measurement, and for example, a beauty sensor that detects skin conditions such as skin texture, and the like. Further, a combination of a light-emitting element that emits near-infrared light and a light-receiving element that receives near-infrared light is applicable to an optical touchless sensor, a human-detecting sensor, and a vital sensing device typified by oxygen saturation measurement. Furthermore, it is possible to use the combination for finger, arm, earlobe, nose, and frontal (forehead) vein imaging devices, and the like. In addition, the combination is also applicable to authentication by imaging of irises and faces, imaging of lymph and sweat glands, and is further applicable to an X-ray plate, mammography, a night vision, a security sensor, an in-vehicle sensor, an aircraft sensor, a factory automation sensor, a gas sensor, a biosensor, and an implant device (a blood flowmeter, a photodynamic therapy, and the like).

### Application Example 7

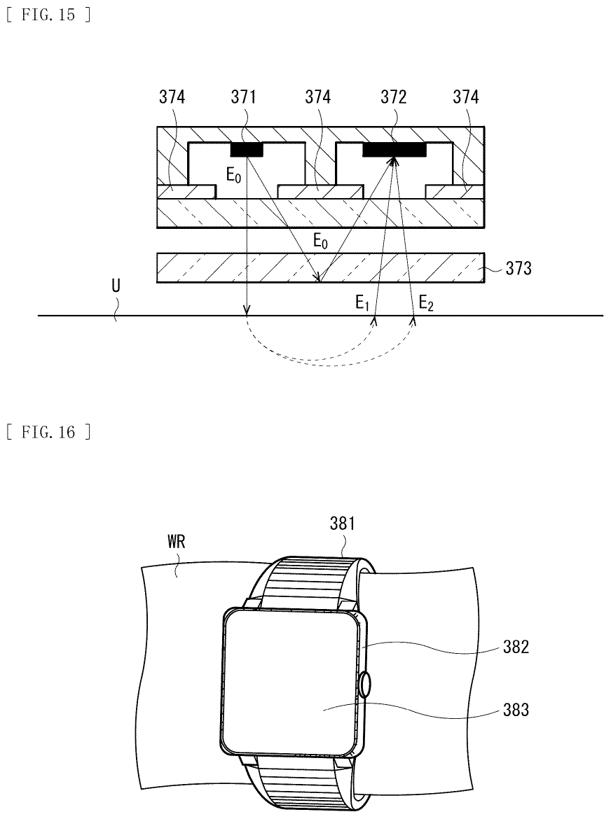

FIG. 15 schematically illustrates a portion of a cross-sectional configuration of a laser Doppler blood flowmeter. The laser Doppler blood flowmeter includes light emitters 371 and 372, a cover 373 including a translucent material, and a shielding layer 374. The light emitter 371 outputs coherent light toward a subject site of a user U, and is incorporated with the light-emitting element 10 according to the above-described embodiment. The cover 373 protects, from foreign matter, a circuit substrate (not illustrated) and the like disposed inside the laser Doppler blood flowmeter.

### Application Example 8

FIG. 16 illustrates an appearance configuration of a wristband electronic apparatus. The wristband electronic apparatus includes a band 381 wound around a wrist WR of a user, and a body unit 382. The body unit 382 includes a display 383. In the wristband electronic apparatus, bringing a fingertip into contact with the display 383 makes it possible to perform biometric authentication using information regarding fingerprints of the fingertip. FIG. 17 schematically illustrates a partial cross-sectional configuration for describing an internal structure of the body unit 382 of the wristband electronic apparatus. The body unit 382 of the wristband electronic apparatus includes, for example, a display 384, a light guide plate 385, a light emitter 386, a touch sensor 387, a sensor 388, and a lens 389. The light emitter 386 is incorporated with the light-emitting element 10 according to the above-described embodiment.

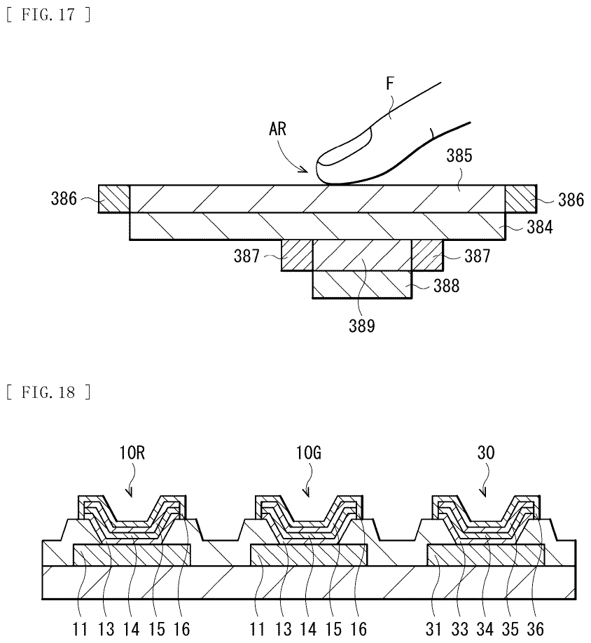

In addition, for example, a combination of the light-emitting elements 10 (e.g., the light-emitting elements 10R and 10G) and a light-receiving element 30 having different light emission wavelengths makes it possible to also exhibit the above-described function in the same substrate and the same device, as illustrated in FIG. 18. In this case, only a functional layer such as a light-emitting layer or a photoelectric conversion layer is changed by, for example, selecting an organic electroluminescent element and an organic photoelectric conversion element each using an organic material, thereby enabling device manufacturing in which addition of processes is suppressed. It is to be noted that the functional layer is not limited to organic materials, and is able to exhibit various functions by changing the kind of the materials such as a quantum dot material or a perovskite material.

### 4. EXAMPLES

Next, description is given of examples of the present disclosure.

### Experiment 1

In Experiment 1, an evaluation element having a configuration similar to that of the above-described light-emitting element 10 was fabricated, and was evaluated for a physical property value, a drive voltage, and light emission electric power efficiency.

### Experimental Example 1

First, an ITO film having a film thickness of 100 nm was formed on an inorganic alkali glass substrate using a sputtering device. This ITO film was processed by a lithography technique using a photomask to form the anode 11. Next, an insulating film was formed on the inorganic alkali glass substrate and the anode 11, and a 2 mm-square opening allowing the anode 11 to be exposed was formed by a lithography technique. Subsequently, a surface thereof was subjected to ultrasonic cleaning sequentially using a neutral detergent, acetone, and ethanol. Next, after drying, the inorganic alkali glass substrate was further subjected to UV/ozone treatment for ten minutes, and was then transferred to a vapor deposition device. A vapor deposition chamber was decompressed to 5.5×10⁻⁵ Pa or less. Subsequently, the hole injection layer 12, the hole transport layer 13, the light-emitting layer 14, the electron transport layer 15, and the electron injection layer 16 were sequentially formed by vacuum deposition film formation using a shadow mask. Specifically, a film of HAT-CN represented by a formula (5) below was formed with a film thickness of 10 nm to serve as the hole injection layer 12. Subsequently, a film of HG-17 represented by a formula (6) below was formed with a film thickness of 30 nm to serve as the hole transport layer 13. Subsequently, DPh-BTBT represented by the above-described formula (3-1) as the host material and Pt (TPBP) represented by a formula (7) below as the dopant material were co-deposited at a vapor deposition rate ratio of 99:1 to form a film with a film thickness of 45 nm, which served as the light-emitting layer 14. Next, a film of NBphen represented by a formula (8) below was formed with a film thickness of 20 nm to serve as the electron transport layer 15. Subsequently, a film of LiF was formed with a film thickness of 0.5 nm to serve as the electron injection layer 16. Subsequently, a film of AlSiCu was formed with a film thickness of 100 nm to serve as the cathode 17. Thereafter, sealing glass to which a drying material was attached was bonded using an ultraviolet curable resin in a nitrogen atmosphere to provide an evaluation element.

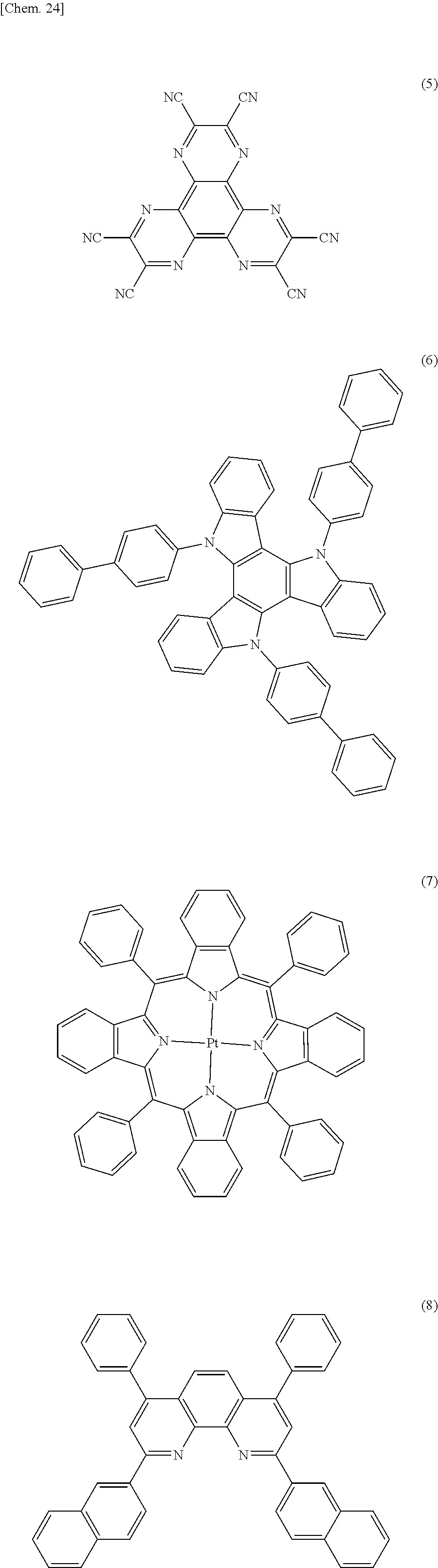

### Experimental Example 2

An evaluation element was fabricated using a method similar to that of Experimental Example 1, except that HG-17 and DPh-BTBT used in Experimental Example 1 were respectively replaced with HT-1 represented by a formula (9) below and DNTT represented by the above-described formula (4-1) to form the hole transport layer 13 and the light-emitting layer 14. It is to be noted that a reason for changing HG-17 to HT-1 is that DNTT used as the host material of the light-emitting layer 14 in the present experimental example has a shallower LUMO level than DPh-BTBT. This allows for formation of an electron barrier between the anode 11 and the light-emitting layer 14 to confine excitons in the light-emitting layer 14.

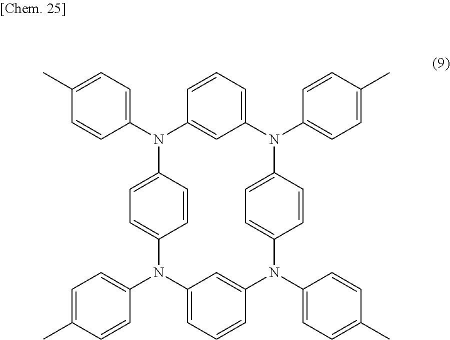

### Experimental Example 3

An evaluation element was fabricated using a method similar to that of Experimental Example 1, except that DPh-BTBT used in Experimental Example 1 was replaced with DMFL-CBP represented by a formula (10) below to form the light-emitting layer 14.

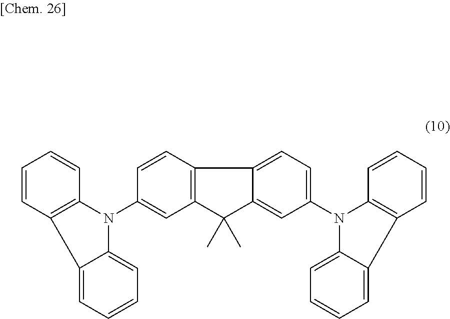 [SMILES: CC1(C)c2cc(-n3c4ccccc4c4ccccc43)ccc2-c2ccc(-n3c4ccccc4c4ccccc43)cc21]

### (Evaluation of Physical Property Value of Organic Semiconductor)

A film of each of the above-described organic semiconductors was formed with a film thickness of 20 nm on a Si substrate, and a surface of the thin film was measured by ultraviolet photoelectron spectroscopy (UPS) to determine each of HOMO levels (ionization potentials) of DPh-BTBT represented by the formula (3-1), DNTT represented by the formula (4-1), and DMFL-CBP represented by the formula (10). In addition, each of HOMO levels (ionization potentials) of the other materials used in Experimental Example 1 was also determined by the same method. An optical energy gap was calculated from an absorption end of an absorption spectrum of each of the thin films of the organic semiconductors, and each of LUMO levels thereof was calculated from a difference between the HOMO and the energy gap (LUMO=−1*|HOMO−energy gap|).

### (Evaluation of Light-Emitting Element: Light Emission Electric Power Efficiency)

Each of the evaluation elements of Experimental Examples 1 to 3 was driven with a direct current of 2.5 mA/cm² using a source meter, and a voltage applied to the evaluation element was measured. Subsequently, an emission spectrum was measured using a fiber spectrometer to calculate radiant flux of light emitted from the element using a total spectral radiant flux standard LED manufactured by NICHIA CORPORATION. Thereafter, the light emission electric power efficiency was calculated using a mathematical expression (1) below.

(Math. 1)

Light emission electric power efficiency(%)={radiant flux of light emitted from element/(current flowing through element×voltage applied to element)}×100 (1)

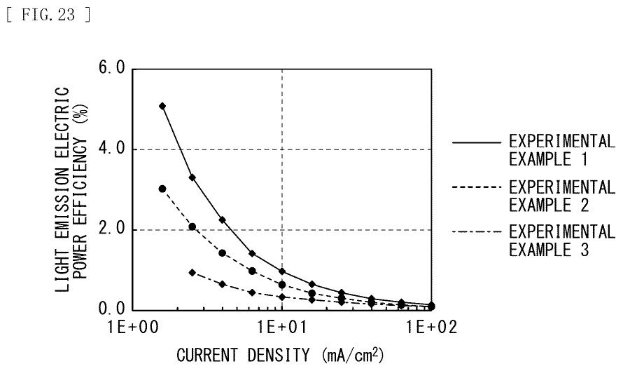

Table 1 summarizes the host materials used for the light-emitting layer in Experimental Examples 1 to 3, carrier mobility, a drive voltage, and light emission electric power efficiency thereof. It is to be noted that values of the light emission electric power efficiency are expressed as relative values in a case where the value of Experimental Example 3 is defined as a reference value (1.0). FIG. 19 illustrates energy levels of the host materials (DPh-BTBT represented by the formula (3-1), DNTT represented by the formula (4-1), and DMFL-CBP represented by the formula (10)) and the dopant material (Pt (TPBP) represented by the formula (7)) used for the light-emitting layer in Experimental Examples 1 to 3. FIGS. 20 to 22 respectively illustrate light emission of the host material and absorption of the dopant material used for the light-emitting layer in Experimental Examples 1 to 3. FIG. 23 illustrates a relationship between the light emission electric power efficiency and current density in Experimental Examples 1 to 3.

TABLE 1

| | | | | Light Emission |
|---|---|---|---|---|
| | | Mobility | Drive | Electric Power |
| | | @5 V | Voltage | Efficiency |
| | Host Material | (cm²/Vs) | (V) | (Relative Ratio) |
| Experimental | Formula (3-1) | 6E−02 | 3.6 | 3.52 |
| Example 1 | | | | |
| Experimental | Formula (4-1) | 3E−03 | 4.9 | 2.21 |
| Example 2 | | | | |
| Experimental | Formula (10) | 4E−05 | 10.6 | 1.00 |
| Example 3 | | | | |

All the evaluation elements of Experimental Examples 1 to 3 exhibited light emission in a near-infrared wavelength region having a peak at about 770 nm. In comparison under a condition of causing 2.5 mA/cm² to flow through each of the evaluation elements, Experimental Example 3 using DMFL-CBP had a drive voltage of 10.6 V, while Experimental Example 12 using DPh-BTBT and DNTT had drive voltages of 3.6 V and 4.9 V. In addition, in a case where the light emission electric power efficiency of Experimental Example 3 using DMFL-CBP was defined as one, Experimental Examples 1 and 2 respectively using DPh-BTBT and DNTT had light emission electric power efficiency of 3.52 and 2.21. That is, Experimental Example 1 using DPh-BTBT as the host material had a lowered voltage by 7.0 V and increased light emission electrode efficiency by 3.5 times, as compared with Experimental Example 3 using DMFL-CBP. Moreover, Experimental Example 2 using DNTT as the host material had a lowered voltage by 5.7 V and increased light emission electrode efficiency by 2.2 times, as compared with Experimental Example 3 using DMFL-CBP. It has been found from the above that the BTBT derivative typified by DPh-BTBT (Experimental Example 1) and the DNTT derivative typified by DNTT (Experimental Example 2) are excellent host materials for the light-emitting layer that make it possible to achieve both a lowered voltage and increased efficiency of light emission.

Although the present technology has been described above with reference to the embodiment, the modification example, the examples, and the application examples, the present disclosure is not limited to the embodiment and the like described above, and may be modified in a variety of ways.

As described above, the effects described herein are merely exemplary and non-limiting, and other effects may be further provided.

It is to be noted that the present technology may have the following configuration. According to the present technology of the following configuration, an organic layer between a first electrode and a second electrode includes at least one kind of a heteroacene derivative having, in a molecule, one skeleton represented by the general formula (1) or the general formula (2) described above. This improves carrier transportability and improves efficiency of transfer of energy to a dopant material in the organic layer. This makes it possible to improve an electrical property.

[1]

A light-emitting element including:
a first electrode:
a second electrode disposed to be opposed to the first electrode; and
an organic layer provided between the first electrode and the second electrode, and including a light-emitting layer, the light-emitting layer including at least one kind of a heteroacene derivative having, in a molecule, one skeleton represented by a general formula (1) or a general formula (2) below,

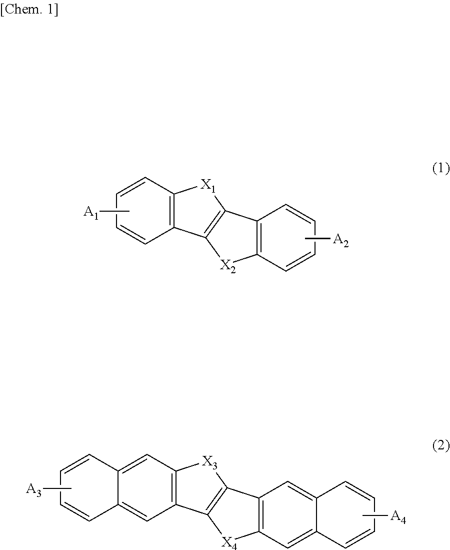

(X1 to X4 are each one of sulfur, oxygen, selenium, or tellurium; and A1 to A4 are each independently a hydrogen atom, an aryl group, a heteroaryl group, an alkyl group, an aryloxy group, a heteroaryloxy group, or an alkoxy group, or a derivative thereof.).
[2]

The light-emitting element according to [1], in which the heteroacene derivative includes at least one of a benzothienobenzothiophene derivative represented by a general formula (3) or a dinaphthothienothiophene derivative represented by a general formula (4) below,

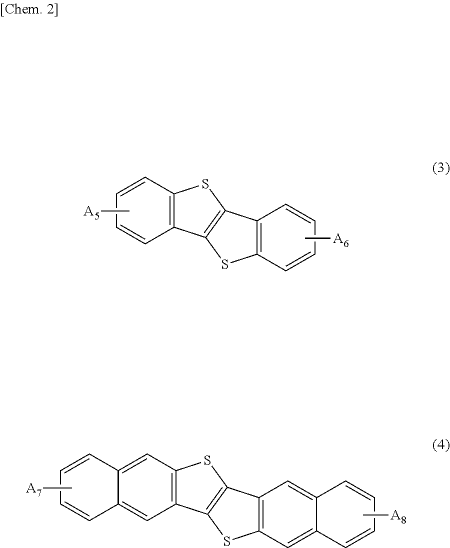

(A5 to A8 are each independently a hydrogen atom, an aryl group having 1 to 30 carbon atoms, a heteroaryl group having 1 to 30 carbon atoms, an alkyl group having 1 to 30 carbon atoms, an aryloxy group having 1 to 30 carbon atoms, a heteroaryloxy group having 1 to 30 carbon atoms, or an alkoxy group having 1 to 30 carbon atoms, or a derivative thereof.).
[3]

The light-emitting element according to [1] or [2], in which the organic layer includes a first buffer layer, the light-emitting layer, and a second buffer layer, the first buffer layer, the light-emitting layer, and the second buffer layer being stacked in this order from a side of the first electrode.

[4]

The light-emitting element according to any one of [1] to [3], in which the light-emitting layer includes at least one kind of a light absorption material having light absorption of 400 nm or more and 900 nm or less.

[5]

The light-emitting element according to [4], in which
an emission spectrum by photoexcitation or electroexcitation of the heteroacene derivative and an absorption spectrum of the light absorption material have an overlap region, and
mobility measured by an SCLC method on a thin film including the heteroacene derivative is larger than 4E-5 cm²/Vs.
   [6]

The light-emitting element according to [4], in which
an emission spectrum by photoexcitation or electroexcitation of the heteroacene derivative and an absorption spectrum of the light absorption material have an overlap region, and
mobility measured by an SCLC method on a thin film including the heteroacene derivative is larger than 3E-3 cm²/Vs.
   [7]

The light-emitting element according to [4], in which
an emission spectrum by photoexcitation or electroexcitation of the heteroacene derivative and an absorption spectrum of the light absorption material have an overlap region, and
mobility measured by an SCLC method on a thin film including the heteroacene derivative is larger than 6E-2 cm²/Vs.
   [8]

The light-emitting element according to any one of [4] to [7], in which the light absorption material has an emission peak in a wavelength range of 410 nm or more and less than 500 nm.

[9]

The light-emitting element according to any one of [4] to [7], in which the light absorption material has an emission peak in a wavelength range of 500 nm or more and less than 750 nm.

[10]

The light-emitting element according to any one of [4] to [7], in which the light absorption material has an emission peak in a wavelength range of 750 nm or more and 1300 m or less.

[11]

The light-emitting element according to any one of [4] to [10], in which the light absorption material includes an iridium complex or a platinum complex.

[12]

The light-emitting element according to any one of [4] to [11], in which
the heteroacene derivative has a HOMO level that is 0.2 eV or more deeper than a HOMO level of the light absorption material, and
the heteroacene derivative has a LUMO level that is 0.2 eV or more shallower than a LUMO level of the light absorption material.
   [13]

The light-emitting element according to any one of [1] to [12], in which at least one of the first electrode or the second electrode includes a transparent electrically conductive material.

[14]

The light-emitting element according to any one of [1] to [12], in which
one of the first electrode or the second electrode includes a transparent electrically conductive material, and
another one of the first electrode or the second electrode includes a metal material.
   [15]

The light-emitting element according to [13] or [14], in which the transparent electrically conductive material includes a metal oxide.

[16]

The light-emitting element according to [15], in which the metal oxide includes ITO, IGO, IZO, IGZO, AZO, GZO, FTO, WOₓ, SnOₓ, TiOₓ, MoOₓ, ZnOₓ, or SbOₓ.

[17]

The light-emitting element according to any one of [14] to [16], in which the metal material includes aluminum, an alloy of aluminum, silicon, and copper, or an alloy of magnesium and silver.

[18]

The light-emitting element according to any one of [1] to [17], in which the first electrode includes a single layer film or a stacked film, the single layer film including an alloy of aluminum and neodymium, an alloy of aluminum and copper, an alloy of aluminum, samarium, and copper, or an alloy of silver, palladium, and copper, the stacked film including a metal film including the alloy and a metal oxide film including a metal oxide.

[19]

The light-emitting element according to any one of [1] to [18], in which at least one of the first electrode or the second electrode has a surface to which a metal nanoparticle adheres.

[20]

The light-emitting element according to any one of [1] to [19], in which a layer adjacent to at least one of the first electrode or the second electrode includes a metal nanoparticle.

[21]

The light-emitting element according to [19], in which the metal nanoparticle includes one of gold, silver, or copper.

[22]

The light-emitting element according to any one of [1] to [21], in which a first light emitter and a second light emitter each including the first electrode, the organic layer, and the second electrode are stacked in this order.

[23]

The light-emitting element according to [22], further including an intermediate electrode between the first light emitter and the second light emitter, in which
the intermediate electrode serves as the second electrode of the first light emitter and the first electrode of the second light emitter, the second electrode of the first light emitter and the first electrode of the second light emitter being adjacent to each other.
   [24]

The light-emitting element according to [22], further including a charge generation layer between the first light emitter and the second light emitter, in which
the charge generation layer serves as the second electrode of the first light emitter and the first electrode of the second light emitter, the second electrode of the first light emitter and the first electrode of the second light emitter being adjacent to each other.
   [25]

The light-emitting element according to any one of [1] to [24], further including a microlens in a direction of a light output surface of the first electrode or the second electrode.

[26]

A light-emitting device including one or more light-emitting elements, in which
the light-emitting elements each include
   a first electrode,
   a second electrode disposed to be opposed to the first electrode, and
   an organic layer provided between the first electrode and the second electrode, and including a light-emitting layer, the light-emitting layer including at least one kind of a heteroacene derivative having, in a molecule, one skeleton represented by a general formula (1) or a general formula (2) below,

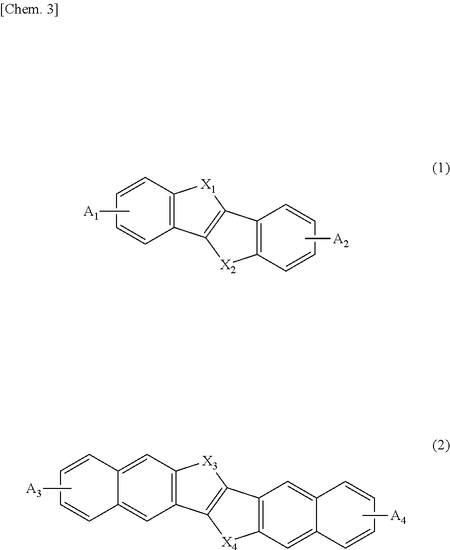

(X1 to X4 are each one of sulfur, oxygen, selenium, or tellurium; and A1 to A4 are each independently a hydrogen atom, an aryl group, a heteroaryl group, an alkyl group, an aryloxy group, a heteroaryloxy group, or an alkoxy group, or a derivative thereof.).
[27]

An electronic apparatus including a light-emitting device including one or more light-emitting elements, in which
the light-emitting elements each include
   a first electrode,
   a second electrode disposed to be opposed to the first electrode, and
   an organic layer provided between the first electrode and the second electrode, and including a light-emitting layer, the light-emitting layer including at least one kind of a heteroacene derivative having, in a molecule, one skeleton represented by a general formula (1) or a general formula (2) below,

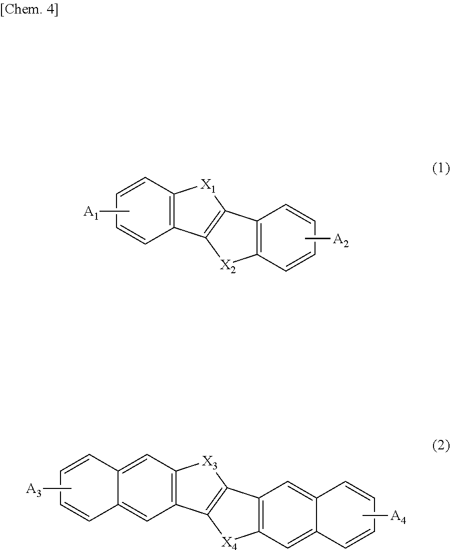

(X1 to X4 are each one of sulfur, oxygen, selenium, or tellurium; and A1 to A4 are each independently a hydrogen atom, an aryl group, a heteroaryl group, an alkyl group, an aryloxy group, a heteroaryloxy group, or an alkoxy group, or a derivative thereof.).

The present application claims the benefit of Japanese Priority Patent Application JP2022-056823 filed with the Japan Patent Office on Mar. 30, 2022, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A light-emitting element comprising:
a first electrode;
a second electrode disposed to be opposed to the first electrode; and
an organic layer provided between the first electrode and the second electrode, and including a light-emitting layer, the light-emitting layer including at least one kind of a heteroacene derivative having, in a molecule, one skeleton represented by a general formula (1) or a general formula (2) below, 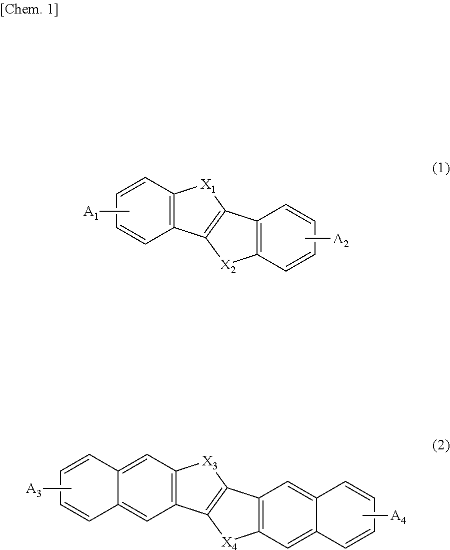
(X1 to X4 are each one of sulfur, oxygen, selenium, or tellurium; and A1 to A4 are each independently a hydrogen atom, an aryl group, a heteroaryl group, an alkyl group, an aryloxy group, a heteroaryloxy group, or an alkoxy group, or a derivative thereof.).

2. The light-emitting element according to claim 1, wherein the heteroacene derivative comprises at least one of a benzothienobenzothiophene derivative represented by a general formula (3) or a dinaphthothienothiophene derivative represented by a general formula (4) below, 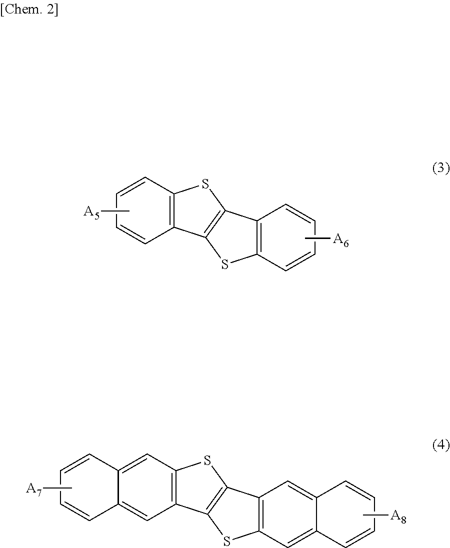
(A5 to A8 are each independently a hydrogen atom, an aryl group having 1 to 30 carbon atoms, a heteroaryl group having 1 to 30 carbon atoms, an alkyl group having 1 to 30 carbon atoms, an aryloxy group having 1 to 30 carbon atoms, a heteroaryloxy group having 1 to 30 carbon atoms, or an alkoxy group having 1 to 30 carbon atoms, or a derivative thereof.).

3. The light-emitting element according to claim 1, wherein the organic layer includes a first buffer layer, the light-emitting layer, and a second buffer layer, the first buffer layer, the light-emitting layer, and the second buffer layer being stacked in this order from a side of the first electrode.

4. The light-emitting element according to claim 1, wherein the light-emitting layer includes at least one kind of a light absorption material having light absorption of 400 nm or more and 900 nm or less.

5. The light-emitting element according to claim 4, wherein
an emission spectrum by photoexcitation or electroexcitation of the heteroacene derivative and an absorption spectrum of the light absorption material have an overlap region, and
mobility measured by an SCLC method on a thin film including the heteroacene derivative is larger than 4E-5 cm²/Vs.

6. The light-emitting element according to claim 4, wherein
an emission spectrum by photoexcitation or electroexcitation of the heteroacene derivative and an absorption spectrum of the light absorption material have an overlap region, and
mobility measured by an SCLC method on a thin film including the heteroacene derivative is larger than 3E-3 cm²/Vs.

7. The light-emitting element according to claim 4, wherein
an emission spectrum by photoexcitation or electroexcitation of the heteroacene derivative and an absorption spectrum of the light absorption material have an overlap region, and
mobility measured by an SCLC method on a thin film including the heteroacene derivative is larger than 6E-2 cm²/Vs.

8. The light-emitting element according to claim 4, wherein the light absorption material has an emission peak in a wavelength range of 410 nm or more and less than 500 nm.

9. The light-emitting element according to claim 4, wherein the light absorption material has an emission peak in a wavelength range of 500 nm or more and less than 750 nm.

10. The light-emitting element according to claim 4, wherein the light absorption material has an emission peak in a wavelength range of 750 nm or more and 1300 m or less.

11. The light-emitting element according to claim 4, wherein the light absorption material comprises an iridium complex or a platinum complex.

12. The light-emitting element according to claim 1, wherein the first electrode includes a single layer film or a stacked film, the single layer film including an alloy of aluminum and neodymium, an alloy of aluminum and copper, an alloy of aluminum, samarium, and copper, or an alloy of silver, palladium, and copper, the stacked film including a metal film including the alloy and a metal oxide film including a metal oxide.

13. The light-emitting element according to claim 1, wherein at least one of the first electrode or the second electrode has a surface to which a metal nanoparticle adheres.

14. The light-emitting element according to claim 1, wherein a layer adjacent to at least one of the first electrode or the second electrode includes a metal nanoparticle.

15. The light-emitting element according to claim 13, wherein the metal nanoparticle comprises one of gold, silver, or copper.

16. The light-emitting element according to claim 1, wherein a first light emitter and a second light emitter each including the first electrode, the organic layer, and the second electrode are stacked in this order.

17. The light-emitting element according to claim 16, further comprising an intermediate electrode between the first light emitter and the second light emitter, wherein
the intermediate electrode serves as the second electrode of the first light emitter and the first electrode of the second light emitter, the second electrode of the first light emitter and the first electrode of the second light emitter being adjacent to each other.

18. The light-emitting element according to claim 16, further comprising a charge generation layer between the first light emitter and the second light emitter, wherein
the charge generation layer serves as the second electrode of the first light emitter and the first electrode of the second light emitter, the second electrode of the first light emitter and the first electrode of the second light emitter being adjacent to each other.

19. The light-emitting element according to claim 1, further comprising a microlens in a direction of a light output surface of the first electrode or the second electrode.

20. An electronic apparatus comprising one or more light-emitting elements, wherein
the light-emitting elements each include
a first electrode,
a second electrode disposed to be opposed to the first electrode, and
an organic layer provided between the first electrode and the second electrode, and including a light-emitting layer, the light-emitting layer including at least one kind of a heteroacene derivative having, in a molecule, one skeleton represented by a general formula (1) or a general formula (2) below, 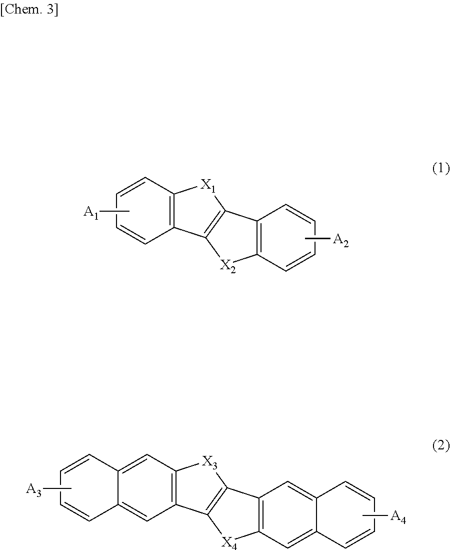
(X1 to X4 are each one of sulfur, oxygen, selenium, or tellurium; and A1 to A4 are each independently a hydrogen atom, an aryl group, a heteroaryl group, an alkyl group, an aryloxy group, a heteroaryloxy group, or an alkoxy group, or a derivative thereof.).
